(19) United States
(12) Patent Application Publication
(10) Pub. No.: US 2016/0117045 A1
(43) Pub. Date: Apr. 28, 2016

(54) Oscillator Circuit, Phase Locked Loop, and Electronic Device

(71) Applicant: Semiconductor Energy Laboratory Co., Ltd., Kanagawa-ken (JP)

(72) Inventors: Shunpei Yamazaki, Tokyo (JP); Yoshiyuki Kurokawa, Sagamihara (JP); Takayuki Ikeda, Atsugi (JP)

(73) Assignee: Semiconductor Energy Laboratory Co., Ltd., Kanagawa-ken (JP)

(21) Appl. No.: 14/922,399

(22) Filed: Oct. 26, 2015

(30) Foreign Application Priority Data
Oct. 27, 2014 (JP) 2014-218013

(51) Int. Cl. G06F 3/041; H03L 7/099; H03B 5/36

(52) U.S. Cl. CPC G06F 3/0416; H03B 5/364; H03L 7/099; G06F 3/0412

(57) ABSTRACT

An oscillator circuit includes a MEMS switch, a transistor, a buffer circuit, and an analog memory. The MEMS switch includes a fixed electrode and a movable electrode. A gate potential of the transistor is retained by the analog memory. The potential of the fixed electrode is controlled by an on-state current of the transistor. A first change and a second change periodically occur in the movable electrode, thereby causing a periodic change in the potential of the fixed electrode. The first change occurs due to electrostatic attraction caused by the potential difference between the fixed electrode and the movable electrode. The second change occurs due to restoring force that is generated when the movable electrode and the fixed electrode have the same potential. The potential of the fixed electrode is output through the buffer circuit.

### BACKGROUND OF THE INVENTION

1. Field of the Invention

One embodiment of the present invention relates to a signal generation circuit such as an oscillator circuit or a phase locked loop, an electronic device, and other semiconductor devices. Another embodiment of the present invention relates to a driving method thereof, a manufacturing method thereof, and the like.

One embodiment of the present invention is not limited to the above technical field. Examples of embodiments of the invention disclosed in the specification, the drawings, and the scope of claims of the present application (they are collectively referred to as “this specification and the like” in the following description) include a processing device, a memory device, a display device, a liquid crystal display device, a light-emitting device, a lighting device, a power storage device, an input device, an imaging device, a driving method thereof, and a manufacturing method thereof.

2. Description of the Related Art

An oscillator circuit is used to generate a clock signal. Use of an oscillator circuit capable of changing its oscillation frequency over a wide range makes it easier to change the operation frequency of a semiconductor device in accordance with needed performance. Such an oscillator circuit is suitable for a sensor network semiconductor device, for example.

Patent Document 1 discloses a MEMS oscillator whose oscillation frequency can be adjusted even after packaging. MEMS means microelectromechanical systems, which are minute electronic devices or electronic systems with a combination of a mechanical portion having a movable minute structure and an electronic circuit for controlling the mechanical portion.

Non-Patent Document 1 discloses a ring-oscillator-based voltage-controlled oscillator (VCO), as an example of a programmable analog device. The VCO in Non-Patent Document 1 includes a nonvolatile programmable analog memory formed using field-effect transistors (FETs) including an oxide semiconductor as their active layers. The oscillation frequency of the VCO can be changed using analog voltage data retained in the analog memory.

### REFERENCE

### Patent Document

[Patent Document 1] Japanese Published Patent Application No. 2012-222718

### Non-Patent Document

[Non-Patent Document 1] Y. Okamoto et al., “CAAC-OS-based Nonvolatile Programmable Analog Device: Voltage Controlled Oscillator Realizing Instant Frequency Switching”, Extended Abstracts of the 2014 International Conference on Solid State Devices and Materials, 2014, pp. 452-453.

### SUMMARY OF THE INVENTION

An object of one embodiment of the present invention is to provide a novel semiconductor device or a method for operating the novel semiconductor device. An object of another embodiment of the present invention is to reduce power consumption, make it possible to change the oscillator frequency, or make it possible to execute operation immediately after power is supplied.

Note that the description of a plurality of objects does not mutually preclude the existence. One embodiment of the present invention does not necessarily achieve all the objects. Objects other than those listed above are apparent from the description of the specification and the like. Such objects could be objects of one embodiment of the present invention.

One embodiment of the present invention is an oscillator circuit including a MEMS switch, a capacitor, a buffer circuit, a first transistor, a second transistor, a first node, and a second node. The MEMS switch includes a movable electrode and a fixed electrode. The fixed electrode is electrically connected to the first node. A first terminal of the capacitor is electrically connected to the first node. An input terminal of the buffer circuit is electrically connected to the first node. A first terminal of the first transistor is electrically connected to the second node. An active layer of the first transistor is formed using an oxide semiconductor. A gate of the second transistor is electrically connected to the second node. A first terminal of the second transistor is electrically connected to the first node. In this embodiment, an active layer of the second transistor may be formed using an oxide semiconductor.

One embodiment of the present invention is an oscillator circuit including a MEMS switch, a capacitor, a buffer circuit, n circuits, a multiplexer, a first node, n first wirings, and a second wiring. The MEMS switch includes a movable electrode and a fixed electrode. The fixed electrode is electrically connected to the first node. A first terminal of the capacitor is electrically connected to the first node. An input terminal of the buffer circuit is electrically connected to the first node. The n circuits are electrically connected to the respective first wirings. The n circuits are electrically connected to the second wiring. The n circuits each comprise a first transistor, a second transistor, and a second node. A first terminal of the first transistor is electrically connected to the second node. A second terminal of the first transistor is electrically connected to the second wiring. An active layer of the first transistor is formed using an oxide semiconductor. A gate of the second transistor is electrically connected to the second node. A first terminal of the second transistor is electrically connected to the multiplexer. The multiplexer has a function of selecting one of the n circuits and electrically connecting the first node and the first terminal of the second transistor of the selected circuit.

In this embodiment, an active layer of the second transistor may be formed using an oxide semiconductor. In addition, in this embodiment, the multiplexer may include n third transistors. The 17 third transistors each have a function of controlling a conduction state between the first node and the first terminal of the corresponding second transistor. An active layer of each of the n third transistors may be formed using an oxide semiconductor.

One embodiment of the present invention can provide a novel semiconductor device or a method for operating the semiconductor device. Another embodiment of the present invention makes it possible to change the oscillator frequency, reduce power consumption, or execute operation immediately after power is supplied.

Note that the description of the plurality of effects does not disturb the existence of other effects. In one embodiment of the present invention, there is no need to achieve all the effects described above. In one embodiment of the present invention, an object other than the above objects, an effect other than the above effects, and a novel feature will be apparent from the description of the specification and the drawings.

### BRIEF DESCRIPTION OF THE DRAWINGS

FIG. 1 is a circuit diagram illustrating a configuration example of an oscillator circuit.

FIG. 2 is a timing chart showing an operation example of an oscillator circuit.

FIGS. 3A and 3B are each a circuit diagram illustrating a configuration example of an oscillator circuit.

FIG. 4 is a circuit diagram illustrating a configuration example of an oscillator circuit.

FIG. 5 is a timing chart showing an operation example of an oscillator circuit.

FIG. 6 is a block diagram illustrating a configuration example of a phase locked loop.

FIG. 7 is a block diagram illustrating a configuration example of a processing unit (wireless IC).

FIG. 8 is a schematic diagram illustrating a configuration example of a processing unit (PLD).

FIG. 9 is a block diagram illustrating a configuration example of a processing unit (MCU).

FIG. 10 is an exploded perspective view illustrating a structure example of a display device.

FIG. 11A is a block diagram illustrating a configuration example of an imaging device, and FIG. 11B is a block diagram illustrating a configuration example of a driving circuit.

FIGS. 12A to 12H illustrate structure examples of electronic devices.

FIG. 13A is a plan view illustrating a structure example of a transistor, and

FIGS. 13B to 13D are cross-sectional views of FIG. 13A.

FIG. 14A is an enlarged view of part of FIG. 13B, and FIG. 14B is an energy band diagram of the transistor.

FIGS. 15A to 15C are cross-sectional views each illustrating a structure example of a transistor.

FIGS. 16A and 16B are cross-sectional views each illustrating a structure example of a transistor.

FIG. 17 is a cross-sectional view illustrating a structure example of a semiconductor device.

FIG. 18 is a cross-sectional view illustrating a structure example of a semiconductor device.

FIG. 19 is a cross-sectional view illustrating a structure example of a semiconductor device.

FIG. 20A is a flow chart showing an example of a method for manufacturing an electronic component, and FIG. 20B is a schematic view illustrating a structure example of the electronic component.

FIGS. 21A to 21C are Cs-corrected high-resolution TEM images of a cross section of a CAAC-OS, and FIG. 21D is a cross-sectional schematic view of a CAAC-OS.

FIGS. 22A to 22D are Cs-corrected high-resolution TEM images of a plane of a CAAC-OS.

FIGS. 23A to 23C show structural analysis of a CAAC-OS and a single crystal oxide semiconductor by XRD.

FIGS. 24A and 24B show electron diffraction patterns of a CAAC-OS.

FIG. 25 shows a change in crystal part of an In—Ga—Zn oxide induced by electron irradiation.

FIGS. 26A and 26B are schematic diagrams illustrating deposition models of a CAAC-OS and an nc-OS.

FIG. 27A illustrates an InGaZnO₄ crystal, and FIGS. 27B and 27C illustrate a pellet.

FIGS. 28A to 28D are schematic diagrams illustrating a deposition model of a CAAC-OS.

### DETAILED DESCRIPTION OF THE INVENTION

In this specification and the like, a semiconductor device refers to a device that utilizes semiconductor characteristics, and means a circuit including a semiconductor element (e.g., a transistor or a diode), a device including the circuit, and the like. The semiconductor device also means any device that can function by utilizing semiconductor characteristics. For example, an integrated circuit, and a chip including an integrated circuit are all semiconductor devices. Moreover, a memory device, a display device, a light-emitting device, a lighting device, an electronic device, and the like themselves might be semiconductor devices, or might each include a semiconductor device.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts. Here, X and Y each denote an object (e.g., a device, an element, a circuit, a wiring, an electrode, a terminal, a node, a conductive film, and a layer).

A transistor is an element having three terminals: a gate, a source, and a drain. The gate can serve as a control terminal for controlling the on/off of the transistor. The two terminals called a source and a drain can function as input/output terminals. Depending on the type of the transistor or levels of potentials applied to the terminals, one of the input/output terminals functions as a source and the other functions as a drain. Therefore, the terms “source” and “drain” can be switched in this specification and the like. In this specification and the like, the two terminals other than the gate may be referred to as a first terminal and a second terminal.

A node can be referred to as a terminal, a wiring, an electrode, a conductive layer, a conductor, an impurity region, or the like in accordance with a circuit configuration, a device structure, and the like. Furthermore, a terminal, a wiring, and the like can be referred to as a node.

A voltage usually refers to a potential difference between a given potential and a reference potential (e.g., a ground potential or a source potential). Thus, a voltage can be referred to as a potential. Note that the potential indicates a relative value. Accordingly, “ground potential” does not necessarily mean 0 V.

Note that in this specification, the terms “film” and “layer” can be interchanged depending on the case or circumstances. For example, a term “conductive layer” can be replaced with a term “conductive film” in some cases. For example, a term “insulating film” can be replaced with a term “insulating layer” in some cases.

In this specification and the like, ordinal numbers such as “first”, “second”, and “third” are used to avoid confusion among components, and the terms do not limit the components numerically or do not limit the order.

In this specification and the like, a power supply potential Vdd may be abbreviated to a potential Vdd, Vdd, or the like, for example. The same applies to other components (e.g., signal, voltage, potential, circuit, element, electrode, and wiring). When the same reference numerals need to be distinguished from each other, “_1”, “_2”, “[n]”, “[m, n]”, or the like may be added to the reference numerals. For example, to distinguish two wirings WL from each other, they are represented as WL[0] and WL[1].

In the drawings, the size, the thickness of a layer, or a region is sometimes exaggerated for simplicity. Therefore, embodiments of the present invention are not limited to such a scale. Note that the drawings are schematic views showing ideal examples, and embodiments of the present invention are not limited to shapes or values shown in the drawings. For example, the following can be included: variation in signal, potential, or current due to noise or difference in timing.

Terms for describing arrangement, such as “over” and “under,” are used for convenience for describing the positional relationship between components with reference to drawings in some cases. Furthermore, the positional relation between components is changed as appropriate in accordance with a direction in which each component is described. Thus, there is no limitation on terms used, and description can be made appropriately depending on the situation.

Note that the layout of circuit blocks in a block diagram illustrated in a drawing specifies the positional relation for description. Thus, even when a drawing shows that different functions are achieved in different circuit blocks, an actual circuit block may be configured so that the different functions are achieved in the same circuit block. Functions of circuit blocks are specified for description, and even when a diagram shows one circuit block performing given processing, a plurality of circuit blocks may be actually provided to perform the processing.

An embodiment of the present invention will hereinafter be described. Note that two or more of the embodiments can be combined as appropriate. In addition, in the case where a plurality of structural examples (including operation examples and manufacturing method examples) is given in one embodiment, any of the structure examples can be combined as appropriate. Furthermore, the present invention can be implemented in various different modes, and it will be readily apparent to those skilled in the art that various changes and modifications in modes and details thereof can be made without departing from the purpose and scope of the present invention. Thus, the present invention should not be interpreted as being limited to the following description of the embodiments.

### Embodiment 1

### <<Configuration Example 1 of Oscillator Circuit>>

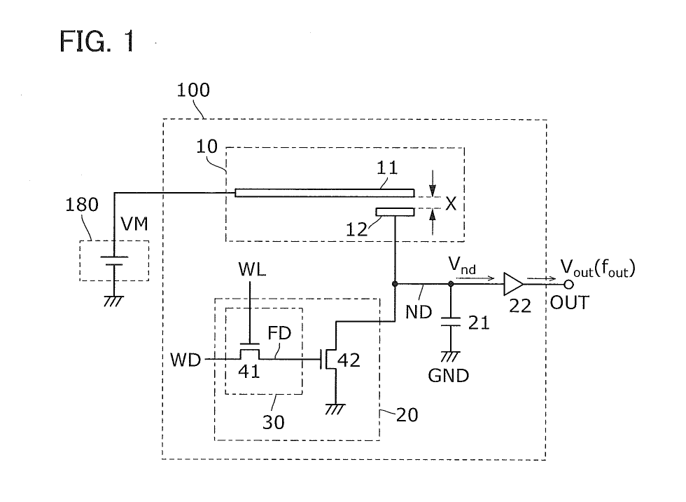

FIG. 1 illustrates a circuit configuration example of an oscillator circuit. An oscillator circuit 100 illustrated in FIG. 1 includes a MEMS switch 10, a circuit 20, a capacitor 21, and a buffer circuit 22.

### (MEMS Switch 10)

The MEMS switch 10 includes a movable electrode 11 and a fixed electrode 12. In the MEMS switch 10, it is possible to make the movable electrode 11 in direct contact with the fixed electrode 12 by changing the shape of the movable electrode 11. Controlling the potential of the fixed electrode 12 causes electrostatic attraction between the movable electrode 11 and the fixed electrode 12 to change the shape of the movable electrode 11. Here, the potential of the movable electrode 11 is controlled by a potential source 180. To fix the potential of the movable electrode 11, a battery can be used as the potential source 180. The fixed electrode 12 is electrically connected to a node ND.

### (Output Portion)

A first terminal of the capacitor 21 is electrically connected to the node ND, and a second terminal thereof is supplied with a ground potential (GND). A resistor R may be inserted to the node ND, whereby an RC series circuit including the resistor R and the capacitor 21 may be formed. The RC series circuit functions as a low-pass filter. An input terminal of the buffer circuit 22 is electrically connected to the node ND, and an output terminal thereof is electrically connected to an output terminal OUT of the oscillator circuit 100. The oscillator circuit 100 has a function of outputting a signal Vₒᵤₜ at an oscillation frequency fₒᵤₜ from the output terminal OUT. The buffer circuit 22 has a function of converting the waveform of the signal Vₒᵤₜ into a rectangular waveform. Furthermore, the buffer circuit 22 may have a function of adjusting the amplitude of the signal Vₒᵤₜ. The buffer circuit 22 can be composed of, for example, one inverter, two or more inverters electrically connected in series, or an amplification circuit.

### (Circuit 20)

The circuit 20 has a function of controlling the potential of the fixed electrode 12 (the node ND). The circuit 20 includes an analog memory 30 and a transistor 42. A gate of the transistor 42 is electrically connected to the analog memory 30. A first terminal of the transistor 42 is electrically connected to the node ND. A second terminal of the transistor 42 is supplied with a ground potential (GND). Although the potential of the second terminal of the transistor 42 is fixed at GND here, one embodiment of the present invention is not limited thereto. The transistor 42 can function as a current source. The magnitude of a current flowing the transistor 42 (a drain current) can be controlled by a potential retained in the analog memory 30.

### (Analog Memory 30)

The analog memory 30 has a function of controlling the gate potential of the transistor 42. The analog memory 30 includes a transistor 41 and a node FD and is electrically connected to a wiring WD and a wiring WL. The node FD serves as a potential retention node of the analog memory 30 and is capable of being in an electrically floating state. The node FD is electrically connected to the gate of the transistor 42. The potential of the node FD is retained owing to parasitic capacitance of the node FD (mainly the gate capacitance of the transistor 42). In order that the potential of the node FD is retained more surely, a capacitor may be electrically connected to the node FD. The transistor 41 is a pass transistor for electrically connecting the wiring WD and the node FD. A gate of the transistor 41 is electrically connected to the wiring WL. A first terminal of the transistor 41 is electrically connected to the node FD. A second terminal of the transistor 41 is electrically connected to the wiring WD.

### (Transistor 41)

Turning off the transistor 41 makes the node FD in an electrically floating state, so that the analog memory 30 is in a retention state. Accordingly, in order to retain an analog potential in the analog memory 30 for a long time, change in the potential (particularly drop of the potential) of the node FD in the electrically floating state is preferably reduced as much as possible. As one method for achieving this, a transistor with an extremely low off-state current is used as the transistor 41, for example.

An off-state current refers to a current (drain current) flowing between a source and a drain of a transistor which is in an off state. In the case of an n-channel transistor, for example, when the threshold voltage of the transistor is approximately 0 V to 2 V, a current flowing between the source and the drain when a voltage between the gate and the source is negative can be referred to as an off-state current.

Extremely low off-state current means that, for example, off-state current per micrometer of channel width is lower than or equal to 100 zA (z represents zepto and denotes a factor of 10⁻²¹). Since the off-state current is preferably as low as possible, the normalized off-state current is preferably lower than or equal to 10 zA/μm or lower than or equal to 1 zA/μm), further preferably lower than or equal to 10 yA/μm (y represents yocto and denotes a factor of 10⁻²⁴).

In order that the off-state current of the transistor is extremely low, the active layer (channel region) of the transistor is formed using a semiconductor with a large energy gap. For example, the energy gap of the semiconductor is greater than or equal to 2.5 eV and less than or equal to 4.2 eV, preferably greater than or equal to 2.8 eV and less than or equal to 3.8 eV, further preferably greater than or equal to 3 eV and less than or equal to 3.5 eV. As an example of such a semiconductor, an oxide semiconductor containing a metal oxide can be given.

A transistor in which the active layer (channel region) is formed using an oxide semiconductor (hereinafter referred to as an OS transistor) has low leakage current due to thermal excitation and extremely low off-state current. The leakage current of an OS transistor normalized on the channel width can be lower than or equal to 10×10⁻²¹ A/μm (10 zA/μm) with a source-drain voltage of 10 V at room temperature (approximately 25° C.). It is preferable that the off-state current of the OS transistor used as the transistor 41 be lower than or equal to 1×10⁻¹⁸ A, lower than or equal to 1×10⁻²¹ A, or lower than or equal to 1×10⁻²⁴ A at room temperature (approximately 25° C.). Alternatively, the leakage current is preferably lower than or equal to 1×10⁻¹⁵ A, lower than or equal to 1×10⁻¹⁸ A, or lower than or equal to 1×10⁻²¹ A at 85° C.

### (Transistor 42)

As described later, the maximum potential of the first terminal of the transistor 42 is a potential VM of the movable electrode 11. To change the shape of the movable electrode 11, it is necessary that the potential VM be a high potential. Accordingly, the transistor 42 is preferably a transistor with high withstand voltage.

An oxide semiconductor is a semiconductor which has a large energy gap and in which electrons are unlikely to be excited and the effective mass of a hole is large. Accordingly, an avalanche breakdown and the like are less likely to occur in an OS transistor than in a generally-used transistor using silicon or the like. Since hot-carrier degradation and the like due to the avalanche breakdown are inhibited, the OS transistor has a high drain withstand voltage and can be driven at a high drain potential. Therefore, use of an OS transistor as the transistor 42 can increase a margin of driving conditions such as a potential for driving the MEMS switch 10 or input timing.

An oxide semiconductor included in the OS transistor is preferably a metal oxide containing at least one or more elements selected from In, Ga, Sn, and Zn. As such a metal oxide, an In—Sn—Ga—Zn oxide, an In—Ga—Zn oxide, an In—Sn—Zn oxide, an In—Al—Zn oxide, a Sn—Ga—Zn oxide, an Al—Ga—Zn oxide, a Sn—Al—Zn oxide, an In—Zn oxide, a Sn—Zn oxide, an Al—Zn oxide, a Zn—Mg oxide, a Sn—Mg oxide, an In—Mg oxide, an In—Ga oxide, an In oxide, a Sn oxide, a Zn oxide, or the like can be used. The oxide semiconductor may contain an element other than the constituent elements of the metal oxide or a compound, and for example, may contain SiO₂.

The OS transistor can have excellent off-state current characteristics and subthreshold characteristics even with a gate insulating layer with an equivalent oxide thickness (EOT) of approximately 11 nm and a short channel length of approximately 50 nm. Since a gate insulating layer in the OS transistor can be thicker than that in a Si transistor generally used in a logic circuit, leakage current through the gate insulating layer can be reduced and a variation in electric characteristics due to a variation in the thickness of the gate insulating layer can be suppressed. Details of the OS transistor are described in Embodiment 2, and details of the oxide semiconductor are described in Embodiment 3.

The maximum potential of the input terminal of the buffer circuit 22 is also VM. Accordingly, also in the buffer circuit 22, a transistor to which the potential VM is input is preferably an OS transistor with a high withstand voltage. For example, use of OS transistors as the transistors 41 and 42 and transistors of the buffer circuit 22 leads to a reduction in manufacturing cost of the oscillator circuit 100. Of OS transistors, only an n-channel transistor has practical characteristics at present. Therefore, in the case where the buffer circuit 22 is formed using OS transistors, the transistors of the buffer circuit 22 are single conductivity type transistors.

### <Driving Method Example of Oscillator Circuit>

In the oscillator circuit 100, the potential of the gate of the transistor 42 is retained in the analog memory 30. The potential of the fixed electrode 12 is controlled by the on-state current of the transistor 42. When the oscillator circuit 100 is operated, a first change and a second change periodically occur in the movable electrode 11. The first change refers to a change in the shape of the movable electrode 11 due to electrostatic attraction caused by the potential difference between the fixed electrode 12 and the movable electrode 11. The second change refers to a change in the shape of the movable electrode 11 due to restoring force that is generated when the movable electrode 11 and the fixed electrode 12 have the same potential. The periodic change in the shape of the movable electrode 11 causes a periodic change in the potential of the fixed electrode 12. The potential of the fixed electrode 12 is input to the buffer circuit 22. The buffer circuit 22 generates the signal Vₒᵤₜ at the oscillation frequency fₒᵤₜ that depends on the potential of the gate of the transistor 42.

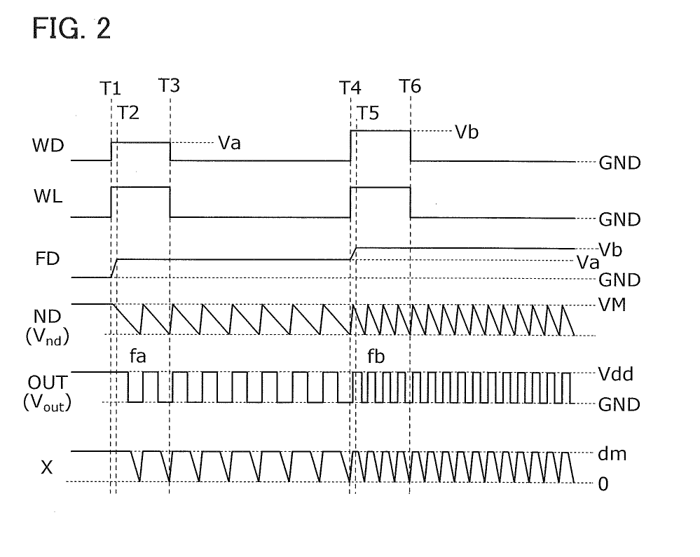

FIG. 2 illustrates an example of a timing chart of the oscillator circuit 100. In FIG. 2, the waveforms of the potentials of the wirings WD and WL, the nodes FD and ND, and the terminal OUT are shown. The minimum value of these potentials is GND. T1 to T6 denote times. Furthermore, FIG. 2 shows a change in a distance X between the movable electrode 11 and the fixed electrode 12 with the passage of time.

### (Initial State)

The potentials of the wirings WD and WL and the node FD are GND in an initial state in which the oscillator circuit 100 does not oscillate. The potential of the movable electrode 11 is fixed at the potential VM by the potential source 180. In the initial state, in order not to generate electrostatic attraction between the movable electrode 11 and the fixed electrode 12, the potential of the node ND (the fixed electrode 12) is also set at VM. Accordingly, the distance X has a maximum value, dm.

### (Writing of Analog Potential)

In a period from T1 to T3, an analog potential is written to the analog memory 30. Specifically, a potential Va of the wiring WD is written to the node FD. At T1, the wiring WL is set at a high-level potential (“H”); thus, the transistor 41 is turned on. Accordingly, the potential of the node FD increases, and then at T2, it becomes the potential Va supplied from the wiring WD. The wiring WL is set at a low-level potential (“L”) at T3, whereby the transistor 41 is turned off. The potential of the wiring WD is returned to GND at T3. In a period from T3 to T4, the analog memory 30 is in a retention state.

### (Oscillation Operation)

When the potential of the node FD exceeds the threshold voltage of the transistor 42, the transistor 42 is turned on. The potential of the node ND decreases because of a current flowing through the transistor 42. The potential of the node ND becomes lower than VM, whereby a potential difference is generated between the movable electrode 11 and the fixed electrode 12 to generate electrostatic attraction between the movable electrode 11 and the fixed electrode 12. The potential difference exceeds a certain value, whereby a mechanical change in the shape of the movable electrode 11 occurs, reducing the distance X. Finally, the distance X reaches 0, that is, the movable electrode 11 is in contact with the fixed electrode 12, so that the potential of the fixed electrode 12 becomes VM. Since the potential of the movable electrode 11 is equal to that of the fixed electrode 12, electrostatic attraction is not generated between the movable electrode 11 and the fixed electrode 12. Thus, the distance X between the movable electrode 11 and the fixed electrode 12 is returned to the initial value dm owing to restoring force of the movable electrode 11.

In a period from T2 to T4, the movable electrode 11 and the fixed electrode 12 are in contact and not in contact with each other repeatedly. A potential V_{nd} of the node ND has a ramp waveform where the rate of fall is lower than the rate of rise. The potential V_{nd} is input to the buffer circuit 22. FIG. 2 shows an example in which the buffer circuit 22 has a function of outputting “H” when the input potential exceeds a predetermined threshold value and outputting “L” when the input potential is lower than the threshold value. A signal Vₒᵤₜ at an oscillation frequency fa is output from the terminal OUT. A high-level potential of the signal \Tₒᵤₜ is determined by a high power supply potential Vdd of the buffer circuit 22.

A spring constant of the movable electrode 11 determines the restoring force of the movable electrode 11. Accordingly, the spring constant of the movable electrode 11 determines a repeated cycle of contact and non-contact between the movable electrode 11 and the fixed electrode 12, i.e., the oscillation frequency fₒᵤₜ of the oscillator circuit 100. A current supply capability of the transistor 42 determines the rate of fall of V_{nd} to determine fₒᵤₜ. The current supply capability of the transistor 42 can be determined by, specifically, the channel length and width of the transistor 42. Furthermore, it is possible to adjust fₒᵤₜ by changing the potential of the gate of the transistor 42. That is, it is possible to adjust fₒᵤₜ by changing a potential which is input to the wiring WD. Therefore, the oscillator circuit 100 can be referred to as a potential-controlled oscillator circuit.

It is possible to change fₒᵤₜ by rewriting the analog potential retained in the analog memory 30. In a period from T4 to T6, a rewriting operation of the analog memory 30 is performed. The wiring WD is set at Vb, and the wiring WL is set at “H”. At T5, the potential of the node FD is rewritten to Vb. At T6, the wiring WL is set at “L”, and the wiring WD is set at GND. After T6, the analog memory 30 is in a retention state.

The potential of the node FD increases to Vb, whereby the drain current of the transistor 42 increases; accordingly, the rate of fall of the node ND increases. Thus, after T5, the terminal OUT outputs a signal Vₒᵤₜ at an oscillation frequency fb which is higher than fa.

Energy for writing an analog potential to the analog memory 30 serves as energy needed for charging and discharging the capacitance of the node FD; therefore, writing to the analog memory 30 can be performed with low power. Furthermore, when an OS transistor with an extremely low off-state current is used as the transistor 41, the potential of the node FD can be retained for a long period; therefore, the analog memory 30 can be used as a nonvolatile memory. Although a generally-used potential-controlled oscillator circuit consumes a power to retain a control potential, the oscillator circuit 100 does not need the power; thus, the dynamic power consumption of the oscillator circuit 100 is reduced. In addition, in the case where power supply is blocked after the potential of the node FD is set so that the oscillator circuit 100 oscillates at a desired frequency, the oscillator circuit 100 can oscillate at the desired frequency immediately after resumption of supply of the power supply potential. That is, the oscillator circuit 100 need not perform a tuning operation every time the power supply potential is supplied to the oscillator circuit 100.

Note that a potential that completely turns off the transistor 41 is being applied to the gate of the transistor 41 during the retention period of the analog memory 30 in some cases. Furthermore, in the case where the transistor 41 has a back gate, a potential is being applied to the back gate in some cases so that the transistor 41 has normally-off characteristics. In such a case, a potential is supplied to the analog memory 30 in the retention period; however, the analog memory 30 hardly consumes power because a current hardly flows. Accordingly, the analog memory 30 hardly consumes power even when supplied with a predetermined potential in the retention period; thus, the analog memory 30 can be referred to as a nonvolatile memory.

### <<Configuration Examples 2 and 3 of Oscillator Circuit>>

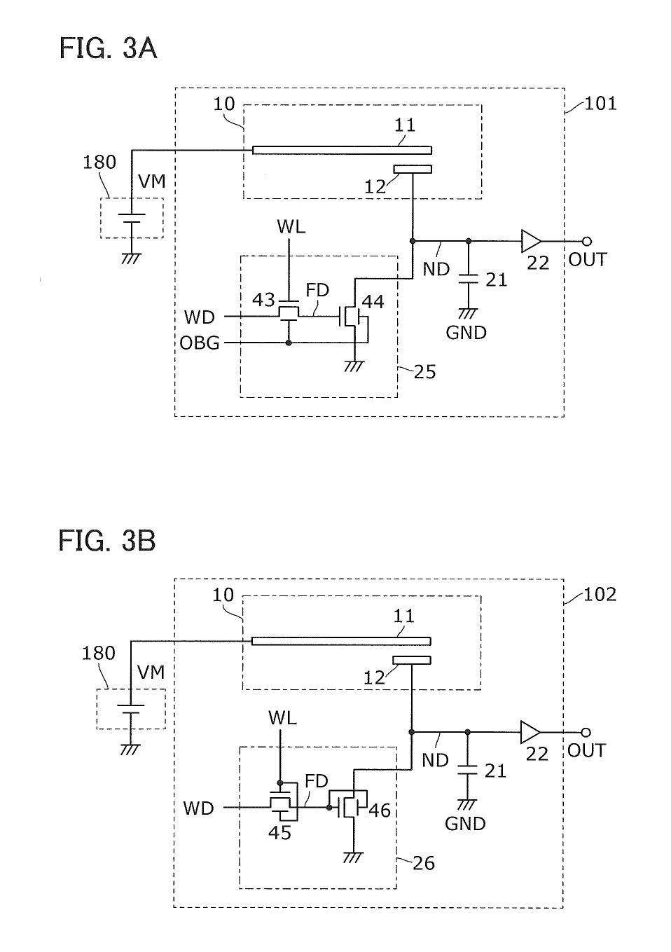

An oscillator circuit 101 illustrated in FIG. 3A and an oscillator circuit 102 illustrated in FIG. 3B are modification examples of the oscillator circuit 100. The oscillator circuits 101 and 102 each can operate in a manner similar to that of the oscillator circuit 100.

The oscillator circuit 101 includes a circuit 25 instead of the circuit 20. The circuit 25 includes transistors 43 and 44 having back gates, instead of the transistors 41 and 42. The back gates of the transistors 43 and 44 are electrically connected to a wiring OBG. A constant potential may be input to the wiring OBG in order to fix the potentials of the back gates of the transistors 43 and 44. Alternatively, the potential of the wiring OBG may be changed in accordance with the operation of the oscillator circuit 101. Adjusting the potentials of the back gates of the transistors 43 and 44 can adjust the threshold voltages thereof.

The transistors 43 and 44 may have no back gates. The back gates of the transistors 43 and 44 may be electrically connected to respective wirings.

The oscillator circuit 102 includes a circuit 26 instead of the circuit 20. The circuit 26 includes, instead of the transistors 41 and 42, transistors 45 and 46 in each of which a back gate is electrically connected to a gate. Such structures of the transistors 45 and 46 can improve their current driving capabilities.

One of the transistors 45 and 46 may have no back gate. Furthermore, the wiring OBG may be provided, and one of the back gates of the transistors 45 and 46 may be electrically connected to the wiring OBG.

### <<Configuration Example 4 of Oscillator Circuit>>

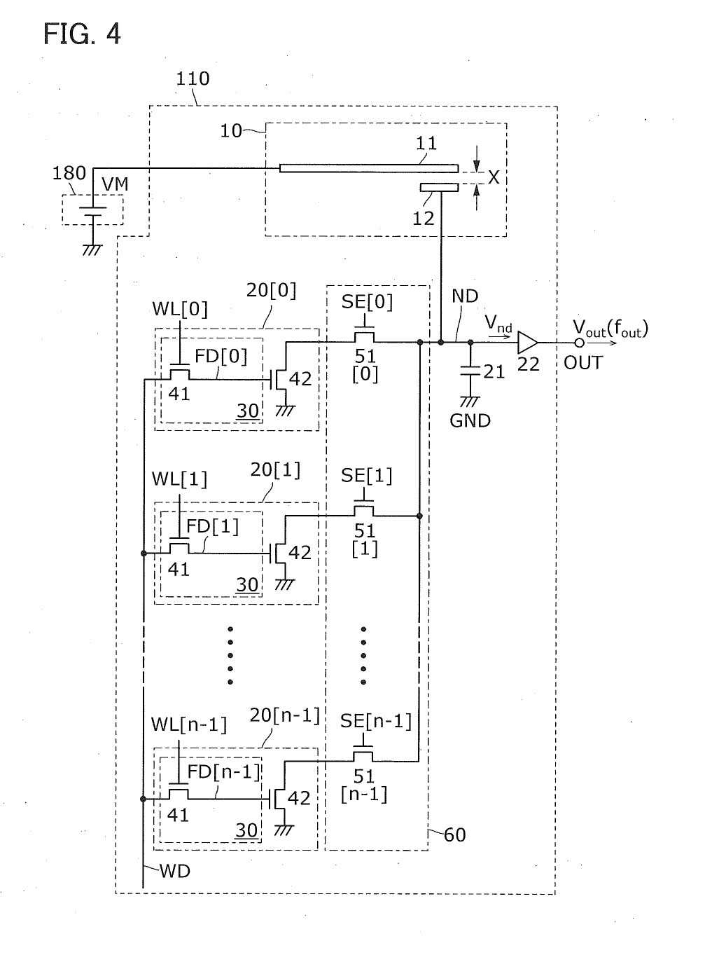

An oscillator circuit 110 illustrated in FIG. 4 is also a potential-controlled oscillator circuit. In the oscillator circuit 110, the oscillation frequency can be switched instantly. The oscillator circuit 110 includes the MEMS switch 10, n circuits 20, the capacitor 21, the buffer circuit 22, and n transistors 51. The movable electrode 11 of the MEMS switch 10 is electrically connected to the potential source 180. Note that reference numerals such as [0] of some components are omitted in FIG. 4.

A circuit 20[k] is electrically connected to the wiring WD and a wiring WL[k]. A gate of a transistor 41[k] is electrically connected to the wiring WL[k], a first terminal thereof is electrically connected to a node FD[k], and a second terminal thereof is electrically connected to the wiring WD. A gate of a transistor 42[k] is electrically connected to the node FD[k], a first terminal thereof is electrically connected to a first terminal of a transistor 51[k], and a second terminal thereof is supplied with GND. A gate of the transistor 51 [k] is electrically connected to a wiring SE[k], and a second terminal thereof is electrically connected to the node ND. k is an integer greater than or equal to 0 and less than or equal to n−1.

Since the potential VM is input to the first and second terminals of the transistor 51 at a maximum, the transistor 51 is preferably a transistor with high withstand voltage in a manner similar to that of the transistor 42. Thus, the transistor 51 is also preferably an OS transistor.

The transistors 51[0] to 51[n−1] form a pass transistor logic 60. The pass transistor logic 60 has a function of a multiplexer. The pass transistor logic 60 is controlled by input signals of wirings SE[0] to SE[n−1]. The transistor 51[k] has a function of controlling the conduction state between an output terminal of the circuit 20[k] (the first terminal of the transistor 42[k]) and the node ND. The pass transistor logic 60 can switch the circuit 20 which is to be electrically connected to the node ND, and thus the oscillator circuit 110 can change the oscillation frequency fₒᵤₜ of the signal Vₒᵤₜ instantly. Furthermore, like the oscillator circuit 100, the oscillator circuit 110 need not perform a tuning operation every time the power supply potential is supplied.

### <Driving Method Example of Oscillator Circuit>

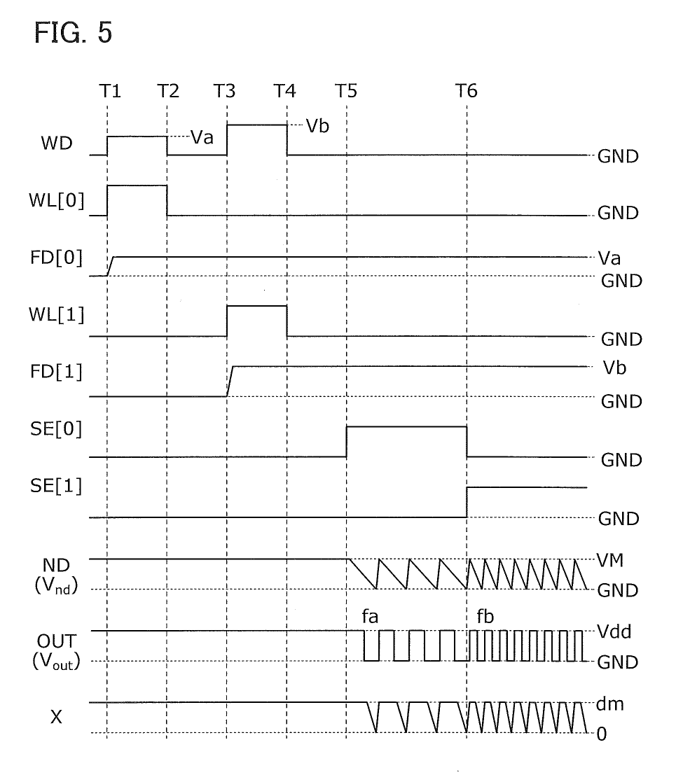

FIG. 5 illustrates an example of a timing chart of the oscillator circuit 110. The timing chart of FIG. 5 shows an example of a method for driving the oscillator circuit 110 in the case where n is 1. In FIG. 5, the waveforms of the potentials of the wiring WD, wirings WL[0] and WL[1], the wirings SE[0] and SE[1], nodes FD[0] and FD[1], the node ND, and the terminal OUT. The minimum value of these potentials is GND. FIG. 5 also shows change in the distance X between the movable electrode 11 and the fixed electrode 12 with the passage of time.

### (Initial State)

The potential of the movable electrode 11 is fixed at the potential VM by the potential source 180 in an initial state in which the oscillator circuit 110 does not oscillate. In the initial state, the potential of the node ND (the fixed electrode 12) is also VM. In the initial state, the distance X has the maximum value, din. The potentials of the wirings WD, WL[0], WL[1], SE[0], and SE[1] and the nodes FD[0] and FD[1] are GND.

### (T1-T4, Writing of Analog Potential)

First, an analog potential is written to analog memories 30[0] and 30[1]. Here, Va is written to the analog memory 30[0] and Vb is written to the analog memory 30[1].

At T1, the wiring WL[0] is set at “H”, and the wiring WD is set at Va. Thus, a transistor 41[0] is turned on, whereby the potential of the node FD[0] is set to the potential Va supplied from the wiring WD. At T2, the wiring WL[0] is set at “L”, and the wiring WD is set at GND. After T2, the analog memory 30[0] is in a retention state.

At T3, the wiring WL[1] is set at “H” and the wiring WD is set at Vd. Thus, a transistor 41[1] is turned on, whereby the potential of the node FD[1] is set to the potential Vb supplied from the wiring WD. At T4, the wiring WL[1] is set at “L” and the wiring WD is set at GND. After T4, the analog memory 30[0] is in a retention state.

### (After T5, Oscillation Operation)

Turning on one of the transistors 51 in the pass transistor logic 60 makes the oscillator circuit 110 oscillate. In a period from T5 to T6, the wiring SE[0] is set at “H”, whereby the transistor 51 [0] is turned on. Accordingly, a first terminal of a transistor 42[0] is electrically connected to the node ND. Thus, like in the oscillation operation of the oscillator circuit 100 in FIG. 2, the movable electrode 11 and the fixed electrode 12 are in contact and not in contact with each other repeatedly at a rate depending on the potential Va of the node FD[0], so that the signal Vₒᵤₜ at the oscillation frequency fa is output from the output terminal OUT.

After T6, since the wiring SE[1] is at “H”, the transistor 51[1] is on. A first terminal of a transistor 42[1] is electrically connected to the node ND. Accordingly, the movable electrode 11 and the fixed electrode 12 are in contact and not in contact with each other repeatedly at a rate depending on the potential Vb of the node FD[1], so that the signal Vₒᵤₜ at the oscillation frequency fb is output from the output terminal OUT.

As described above, changing the potentials of the wirings SE[0] and SE[1] from “H” to “L” or from “L” to “H” enables instant switching of the oscillation frequency fₒᵤₜ. Furthermore, since the analog memories 30[0] and 30[1] can retain the analog potentials for a long time, a tuning operation is not necessarily performed every time power is supplied to the oscillator circuit 110. The same applies to the case where the number of analog memories 30 is three or more.

When the transistor 41 is an OS transistor, the analog memory 30 can be used as a nonvolatile memory, and an analog potential written to the analog memory 30 can be retained for a long time. Energy needed for writing an analog potential to the analog memory 30 serves as energy necessary for charging and discharging the capacitance of the node FD; therefore, writing can be performed with low power consumption. Furthermore, retention of the analog potential in the analog memory 30 consumes substantially no power. Thus, even when a plurality of analog memories 30 is provided, the power consumption of the oscillator circuit 110 hardly increases as compared to that of the oscillator circuit 100. Thus, when power supply is blocked after the potential of the node FD of each analog memory 30 is set so that the oscillator circuit 110 oscillates at a desired frequency, the oscillator circuit 110 can oscillate at the desired frequency immediately after resumption of supply of the power supply potential. Furthermore, in the oscillator circuit 110, fₒᵤₜ can be instantly switched only by control of the potentials of the n wirings SE during an oscillation operation.

### <<Configuration Example of PLL>>

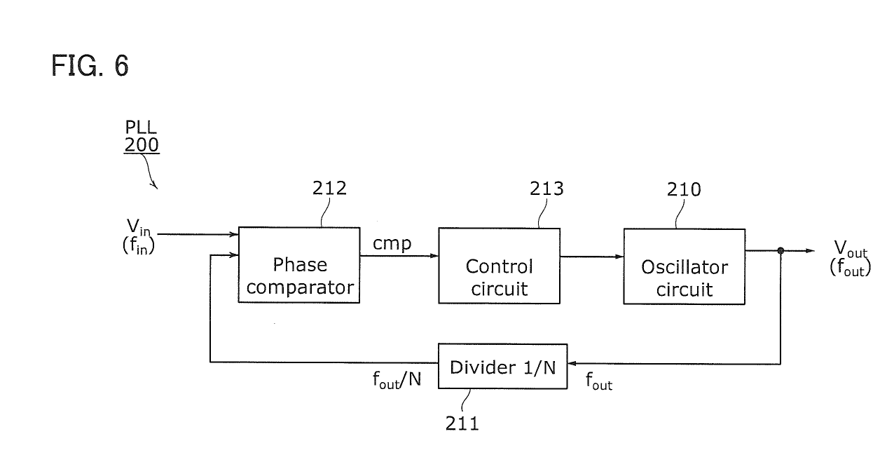

The above oscillator circuit can function as a clock generation circuit. Furthermore, the above oscillator circuit can be used as a potential-controlled oscillator circuit of a phase locked loop (PLL). FIG. 6 illustrates a configuration example of a PLL.

A PLL 200 illustrated in FIG. 6 includes an oscillator circuit 210, a divider 211, a phase comparator 212, and a control circuit 213. The PLL 200 has a function of outputting the signal Vₒᵤₜ at the oscillation frequency fₒᵤₜ. For example, the signal Vₒᵤₜ is input as a clock signal to another circuit.

The divider 211 has a function of generating a signal whose frequency is 1/N times (N is an integer of two or more) the frequency of an alternating-current signal that is input. In the example of FIG. 6, the divider 211 outputs a signal at a frequency fₒᵤₜ/N. The phase comparator 212 has a function of detecting a phase difference between two input signals and generating a potential signal cmp representing the detected result. In the example of FIG. 6, the phase comparator 212 generates the potential signal cmp corresponding to a phase difference between a signal Vᵢₙ at an oscillation frequency fᵢₙ and the signal at the frequency fₒᵤₜ/N. The control circuit 213 has a function of controlling the oscillator circuit 210 on the basis of the signal cmp and the like.

For example, in the case where the oscillator circuit 210 is the oscillator circuit 100 in FIG. 1, the control circuit 213 has a function of controlling the potentials of the wirings WD and WL. The control circuit 213 controls the potential of the wiring WD on the basis of the potential of the signal cmp. The control circuit 213 sets the potential of the wiring WD so that fₒᵤₜ/N is equal to fᵢₙ, whereby an analog potential is written to the analog memory 30.

For example, in the case where the oscillator circuit 210 is the oscillator circuit 110 in FIG. 4, the control circuit 213 has a function of controlling the potentials of the wirings WD, WL[0] to WL[n−1], and SE[0] to SE[n−1]. The control circuit 213 controls the wirings WD and WL[0] to WL[n−1], so that an analog potential is written to the n analog memories 30. The control circuit 213 inputs a signal at “H” to one of the wirings SE[0] to SE[n−1] on the basis of the potential of the signal cmp so that fₒᵤₜ/N is equal to fᵢₙ.

### <<Processing Unit>>

The oscillator circuit and the PLL of this embodiment can be incorporated in a processing unit, for example, and can function as a clock generation circuit. With the processing unit including the oscillator circuit or the PLL of this embodiment, the operation frequency of the semiconductor device can be easily changed in accordance with needed performance; therefore, the processing unit is extremely suitable for a sensor network processing unit.

Examples of the processing unit include a central processing unit (CPU), a graphics processing unit (GPU), a programmable logic device (PLD), a digital signal processor (DSP), a microcontroller unit (MCU), a custom LSI, and a wireless IC.

### <Wireless IC>

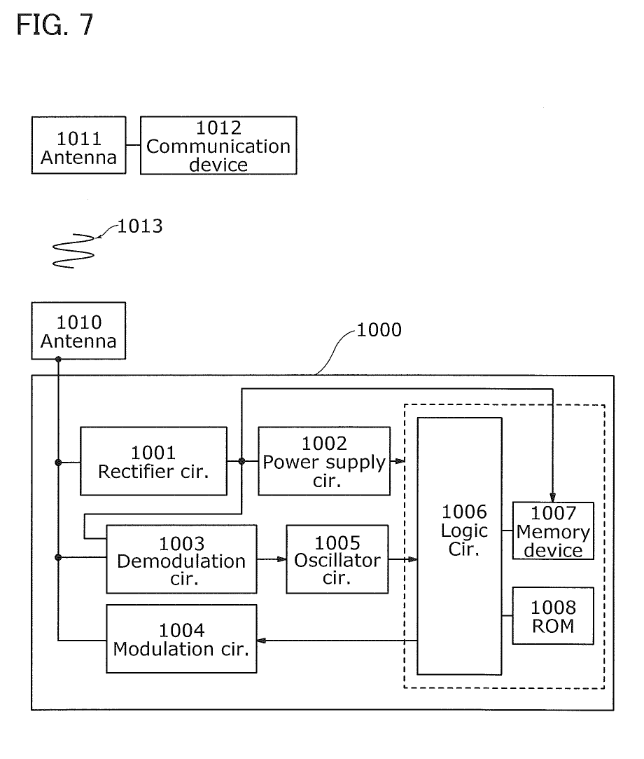

A carrier wave or a clock signal synchronized with a demodulated signal can be generated, for example, by incorporating an oscillator circuit in a wireless IC. FIG. 7 shows an example of a wireless IC. The wireless IC may be referred to as a wireless chip, an RFIC, an RF chip, or the like.

A wireless IC 1000 illustrated in FIG. 7 includes a rectifier circuit 1001, a power supply circuit 1002, a demodulation circuit 1003, a modulation circuit 1004, an oscillator circuit 1005, a logic circuit 1006, a memory device 1007, and a read-only memory (ROM) 1008. Note that decision whether each of these circuits is provided or not can be made as appropriate as needed. The wireless IC 1000 is electrically connected to an antenna 1010. The oscillator circuit and the PLL of this embodiment can be used as the oscillator circuit 1005.

The kind of the wireless IC 1000 is not specifically limited. The wireless IC 1000 in FIG. 7 is a passive wireless IC; however, the wireless IC 1000 may be an active wireless IC with a built-in battery. A communication method of the wireless IC 1000, a structure of the antenna 101, and the like can be determined depending on a frequency band to be used.

The antenna 1010 exchanges a radio signal 1013 with the antenna 1011 which is connected to a communication device 1012. The antenna 1010 has performance corresponding to its communication zone. Note that as data transmission methods, the following methods can be given: an electromagnetic coupling method in which a pair of coils is provided so as to face each other and communicates with each other by mutual induction, an electromagnetic induction method in which communication is performed using an induction field, and a radio wave method in which communication is performed using a radio wave.

The rectifier circuit 1001 generates an input potential by rectification, for example, half-wave voltage doubler rectification of an input alternating signal generated by reception of a radio signal at the antenna 1010 and smoothing of the rectified signal with a capacitor element provided in a lower stage. Note that a limiter circuit may be provided on an input side or an output side of the rectifier circuit 1001. The limiter circuit controls electric power so that electric power which is higher than or equal to certain electric power is not input to a circuit in a later stage if the amplitude of the input alternating signal is high and an internal generation voltage is high.

The power supply circuit 1002 generates a stable power supply voltage from an input potential and supplies it to each circuit. Note that the power supply circuit 1002 may include a reset signal generation circuit. The reset signal generation circuit is a circuit which generates a reset signal of the logic circuit 1006 by utilizing rise of the stable power supply voltage.

The demodulation circuit 1003 demodulates the input alternating signal by envelope detection and generates a demodulated signal. The modulation circuit 1004 performs modulation in accordance with data to be output from the antenna 1010. The oscillator 1005 is a circuit for generating a clock signal synchronized with the demodulated signal.

The logic circuit 1006 has a function of decoding the demodulated signal and performing processing based on the decoded result. The logic circuit 1006 includes, for example, a code recognition/determination circuit, an encoding circuit 1009, and the like. The code recognition/determination circuit analyzes a code of the demodulated signal based on a clock signal to obtain corresponding data. The logic circuit 1006 communicates data with the memory device 1007 in accordance with the analyzed code.

The data output from the memory device 1007 is encoded in an encoding circuit. An encoded signal is output to the modulation circuit 1004.

The memory device 1007 retains an input data and includes a row decoder, a column decoder, a memory region, and the like. The ROM 1008 stores an identification number (ID) and the like and outputs data in accordance with the processing of the logic circuit 1006.

### <PLD>

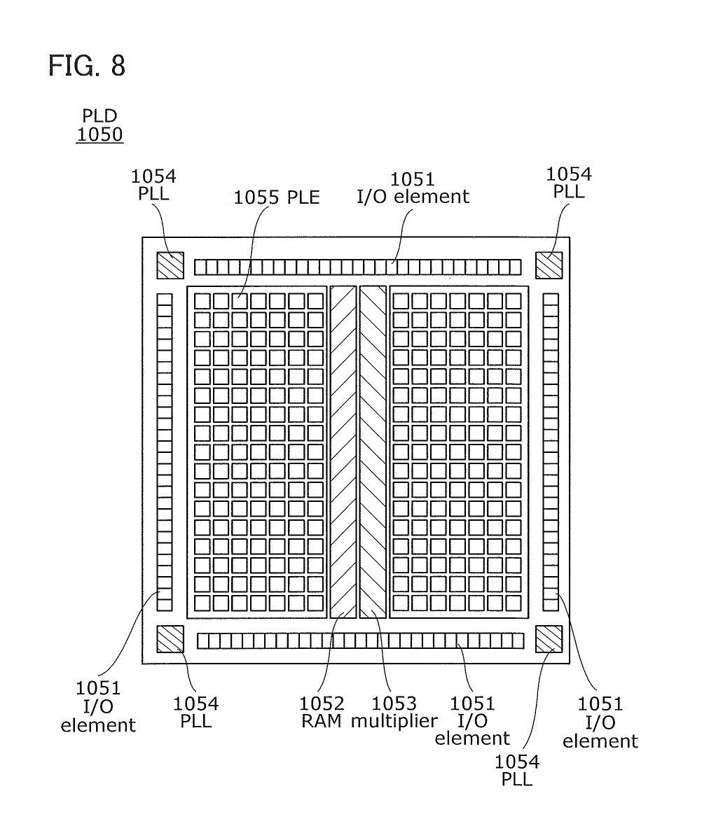

FIG. 8 illustrates an example of a programmable logic device (PLD). A PLD 1050 in FIG. 8 includes an input output (I/O) element 1051, a random access memory (RAM) 1052, a multiplier 1053, a PLL 1054, and a programmable logic element (PLE) 1055. The I/O element 1051 functions as an interface that controls input of a signal from a circuit outside the PLD 1050 or output of a signal to the circuit outside the PLD 1050. The PLL 1054 has a function of generating a clock signal. The RAM 1052 has a function of storing data used for logical operation. The multiplier 1053 corresponds to a logic circuit for multiplication. When the PLD 1050 includes a function of executing multiplication, the multiplier 1053 is not necessarily provided.

### <MCU>

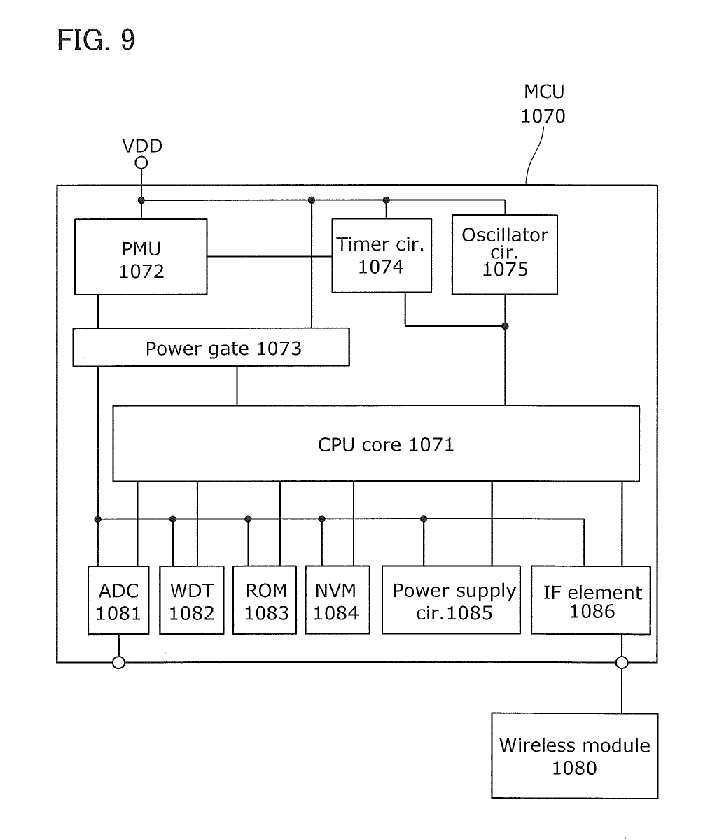

FIG. 9 illustrates an example of a microcontroller unit (MCU). An MCU 1070 in FIG. 9 includes a CPU core 1071, a power source management unit (PMU) 1072, a power gate 1073, a timer circuit 1074, an oscillator circuit 1075, an analog-digital converter (ADC) 1081, a watchdog timer (WDT) 1082, a ROM 1083, a nonvolatile memory (NVM) 1084, a power supply circuit 1085, and an interface (IF) element 1086.

The oscillator circuit 1075 has a function of generating a clock signal. The clock signal is output to internal circuits such as the CPU core 1071 and the timer circuit 1074. The CPU core 1071 and the timer circuit 1074 have a function of performing processing using the clock signal. The PMU 1072 controls the power gate 1073 and controls the supply of the power supply potential VDD to the internal circuit of the MCU 1070. The power supply potential VDD can be supplied to the timer circuit 1074 and the oscillator circuit 1075 without passing through the power gate 1073. The PMU 1072 controls the power gate 1073 so as to stop supply of power to the internal circuit that does not need to operate.

FIG. 9 shows an example in which the MCU 1070 is used for a sensor network. Here, a wireless module 1080 is connected to the IF element 1086, and a semiconductor device such as a sensor unit is connected to the ADC 1081. The wireless module 1080 includes, for example, the wireless IC 1000 illustrated in FIG. 7. The MCU 1070 is capable of processing a signal input to the ADC 1081 and performing control so that the wireless module 1080 transmits the processed result to the other wireless modules. Alternatively, the MCU 1070 is capable of processing a received signal of the wireless module 1080 and performing control so that the wireless module 1080 transmits the processed result to the other wireless module.

The power gate 1073 is turned on by the PMU 1072, whereby the CPU core 1071, the WDT 1082, the ROM 1083, the power supply circuit 1085, and the IF element 1086 operate. Data that is arithmetically processed in the CPU core 1071 is output to the wireless module 1080 via the IF element 1086. The wireless module 1080 wirelessly transmits data. An output signal of the wireless module 1080 is input to the ADC 1081 via the IF element 1086. The ADC 1081 converts the input signal to a digital signal and outputs it to the CPU core 1071. The input signal is arithmetically processed by the CPU core 1071. The signal that is arithmetically processed is output to the wireless module 1080 via the IF element 1086. The wireless module 1080 wirelessly transmits the data. After the transmission, the PMU 1072 turns off the power gate 1073, and stops supply of power to the CPU core 1071 and the like. After the supply of power is stopped, the PMU 1072 controls the timer circuit 1074, and starts time measurement. When the time measurement of the timer circuit 1074 reaches a set value, the PMU 1072 restarts the supply of power to the CPU core 1071 and the like by turning on the power gate 1073 again.

### <<Display Device>>

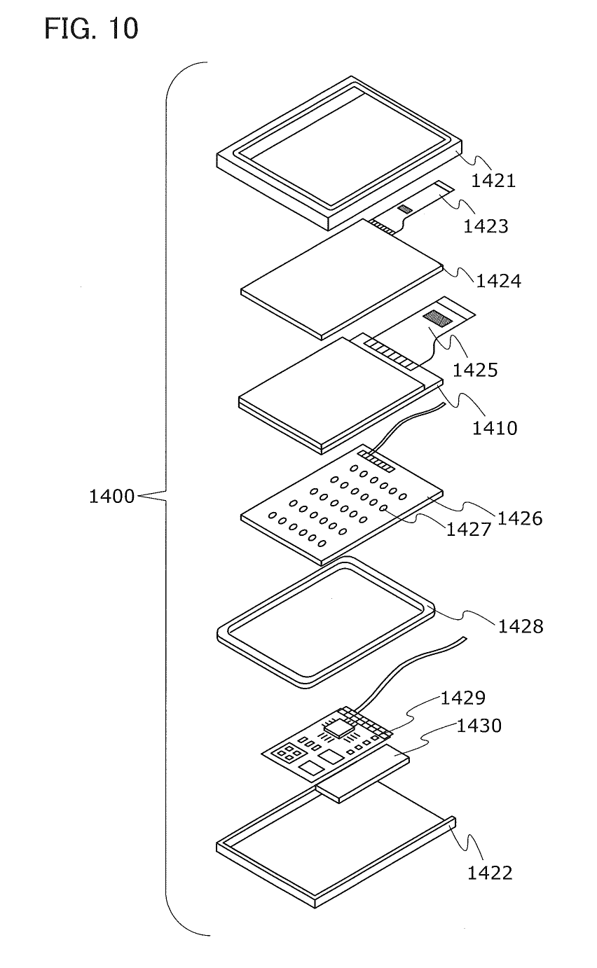

The oscillator circuit or the PLL is incorporated so that a clock signal is supplied to a driver circuit of a display device. FIG. 10 shows an example of the display device. FIG. 10 is an exploded perspective view of the display device.

As shown in FIG. 10, in a display device 1400, a touch screen unit 1424 connected to an FPC 1423, a display panel 1410 connected to an FPC 1425, a backlight unit 1426, a frame 1428, a printed board 1429, and a battery 1430 are provided between an upper cover 1421 and a lower cover 1422. Note that the decision whether these are provided or not can be made as appropriate. The backlight unit 1426, the battery 1430, the touch screen unit 1424, and the like are not provided in some cases. For example, in the case where the display device 1400 is a reflective liquid crystal display device or an electroluminescent (EL) display device, the backlight unit 1426 is unnecessary. The display device 1400 may be additionally provided with a member such as a polarizing plate, a retardation plate, or a prism sheet.

The shapes and sizes of the upper cover 1421 and the lower cover 1422 can be changed as appropriate in accordance with the sizes of the touch screen unit 1424 and the display panel 1410.

The touch screen unit 1424 can be a resistive touch panel or a capacitive touch panel and may be formed so as to overlap the display panel 1410. A counter substrate (sealing substrate) of the display panel 1410 can have a touch panel function. Alternatively, a photosensor may be provided in each pixel of the display panel 1410 to form an optical touch panel. An electrode for a touch sensor may be provided in each pixel of the display panel 1410 so that a capacitive touch panel is obtained.

The backlight unit 1426 includes a light source 1427. The light source 1427 may be provided at an end portion of the backlight unit 1426 and a light diffusing plate may be used.

The frame 1428 protects the display panel 1410 and functions as an electromagnetic shield for blocking electromagnetic waves generated by the operation of the printed board 1429. The frame 1428 may function as a radiator plate.

The printed board 1429 is provided with a power supply circuit and a signal processing circuit for outputting a video signal and a clock signal. The oscillator circuit or the PLL is incorporated in the signal processing circuit. A clock signal generated in the oscillator circuit or the PLL is supplied to the driver circuit of the display panel 1410, and the driver circuit of the touch screen unit 1424. As a power source for supplying power to the power supply circuit, an external commercial power source or a power source using the battery 1430 provided separately may be used. The battery 1430 can be omitted in the case of using a commercial power source.

### <<Imaging Device>>

The oscillator circuit or the PLL can be incorporated in an imaging device. For example, a clock signal generated in the oscillator circuit or the PLL is input to a driver circuit that drives a pixel portion.

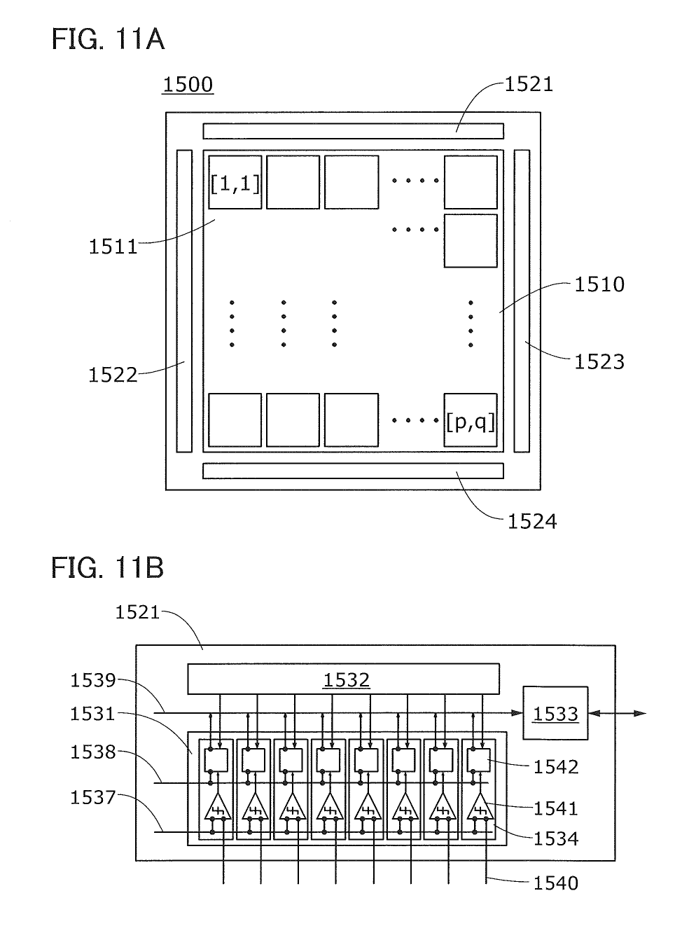

An imaging device 1500 in FIG. 11A includes a pixel portion 1510, a driver circuit 1521, a driver circuit 1522, a driver circuit 1523, and a driver circuit 1524.

The pixel portion 1510 includes a plurality of pixels 1511 (imaging elements) arranged in matrix with p rows and q columns (p and q are each an integer greater than or equal to 2). The driver circuits 1521 to 1524 are each electrically connected to the pixels 1511 and supply signals for driving the pixel portion 1510. The pixels 1511 include photoelectric conversion elements and pixel circuits. The pixel circuit generates an analog signal corresponding to the amount of light received by the photoelectric conversion element.

For example, the driver circuit 1522 or the driver circuit 1523 has a function of generating and outputting a selection signal for selecting a pixel 1511 from which a signal is read. Note that the driver circuit 1522 or the driver circuit 1523 is referred to as a row selection circuit or a vertical driver circuit in some cases. In the driver circuits 1521 to 1524, at least one of them may be omitted. For example, one of the driver circuit 1521 and the driver circuit 1524 may be omitted, and the function of the omitted driver circuit may be added to the other driver circuit. For example, one of the driver circuit 1522 and the driver circuit 1523 may be omitted, and the function of the omitted driver circuit may be added to the other driver circuit. For example, one of the driver circuits 1521 to 1524 may have the functions of all of the driver circuits 1521 to 1524, and the other driver circuits may be omitted.

For example, the driver circuit 1521 or the driver circuit 1524 has a function of processing an analog signal output from the pixels 1511. For example, FIG. 11B shows a configuration example of the driver circuit 1521. The driver circuit 1521 in FIG. 11B may include a signal processing circuit 1531, a column driver circuit 1532, and an output circuit 1533.

The signal processing circuit 1531 includes a circuit 1534 provided for each column. The circuit 1534 can have a function of performing signal processing such as removal of noise and analog-digital conversion. The circuit 1534 shown in FIG. 11B has a function of analog-digital conversion. The signal processing circuit 1531 can function as a column-parallel (column type) analog-digital conversion device.

The circuit 1534 includes a comparator 1541 and a counter circuit 1542. The comparator 1541 has a function of comparing potentials of an analog signal input from a wiring 1540 that is provided in each column and a reference potential signal (e.g., a ramp wave signal) input from a wiring 1537. A clock signal is input to a wiring 1538 from the oscillator circuit or the PLL. The counter circuit 1542 has a function of measuring the length of a period during which a first value is output by the comparison operation in the comparator 1541 and holding the measurement result as an N-bit digital value.

The column driver circuit 1532 is also referred to as a column selection circuit, a horizontal driver circuit, or the like. The column driver circuit 1532 generates a selection signal for selecting a column from which a signal is read. The column driver circuit 1532 can be formed using a shift register or the like. Columns are sequentially selected by the column driver circuit 1532, and an output signal from the circuit 1534 in the selected column is input to the output circuit 1533 via a wiring 1539. The wiring 1539 can function as a horizontal transfer line.

A signal input to the output circuit 1533 is processed in the output circuit 1533, and is output outside the imaging device 1500. The output circuit 1533 can be formed using a buffer circuit, for example. The output circuit 1533 may have a function of controlling the timing at which a signal is output outside the imaging device 1500.

### <Electronic Device>

The variety of processing units and the semiconductor device such as a display device or an imaging device can be incorporated in various electronic devices. For example, when the wireless IC in FIG. 7 is incorporated in an electronic device, the electronic device can have a wireless communication function. For example, when the display device in FIG. 10 is incorporated in an electronic device, the electronic device can have an information display function. For example, the imaging device in FIG. 11A is incorporated in an electronic device, the electronic device can have an imaging function.

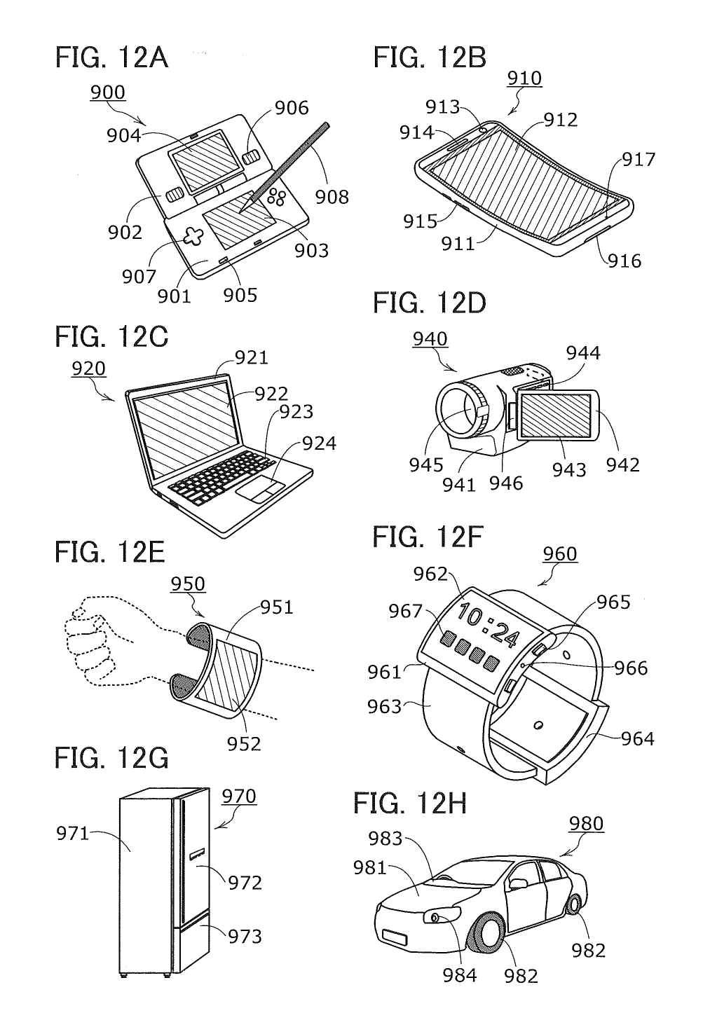

As the electronic device, electronic devices in a wide variety of fields can be given; for example, digital signal processing, software-defined radio systems, avionic systems (electronic devices used in aircraft, such as communication systems, navigation systems, autopilot systems, and flight management systems), ASIC prototyping, medical image processing, voice recognition, encryption, bioinformatics, emulators for mechanical systems, and radio telescopes in radio astronomy. Other examples of such an electronic device include display devices, personal computers (PCs), or image reproducing devices provided with recording media (typically, devices which reproduce the content of recording media such as digital versatile discs (DVDs) and blue-ray discs and have displays for displaying the reproduced images). Other examples of the electronic device are mobile phones, game machines including portable game machines, portable data appliances, e-book readers, cameras (e.g., video cameras and digital still cameras), wearable display devices or terminals (e.g., head mounted display devices, goggle-type display devices, glasses-type display devices, armband display devices, bracelet-type display devices, and necklace-type display devices), navigation systems, audio reproducing devices (e.g., car audio systems and digital audio players), copiers, facsimiles, printers, multifunction printers, automated teller machines (ATM), vending machines, and health-related devices (e.g., blood-pressure meters, blood sugar level measuring devices, physical activity meters, pedometers, and weight meters). FIGS. 12A to 12H show examples of the electronic devices.

A portable game machine 900 shown in FIG. 12A includes a housing 901, a housing 902, a display portion 903, a display portion 904, a microphone 905, a speaker 906, an operation key 907, and the like. The display portion 903 is provided with a touch screen as an input device, which can be handled with a finger, a stylus 908, or the like.

An information terminal 910 shown in FIG. 12B includes a housing 911, a display portion 912, a microphone 917, a speaker portion 914, a camera 913, an external connection portion 916, and an operation button 915. A display panel that uses a flexible substrate and a touch screen are provided in the display portion 912. The information terminal 910 can be used as, for example, a smartphone, a mobile phone, a tablet information terminal, a tablet PC, or an e-book reader.

A notebook PC 920 illustrated in FIG. 12C includes a housing 921, a display portion 922, a keyboard 923, and a pointing device 924. The notebook PC 920 may include an imaging device to have an imaging function. Furthermore, the notebook PC 920 may include a wireless IC to be capable of transmitting and receiving data.

A video camera 940 illustrated in FIG. 12D includes a housing 941, a housing 942, a display portion 943, operation keys 944, a lens 945, a joint 946, and the like. An imaging device is incorporated in the housing 941. The operation keys 944 and the lens 945 are provided in the housing 941, and the display portion 943 is provided in the housing 942. The housing 941 and the housing 942 are connected to each other with the joint 946, and an angle between the housing 941 and the housing 942 can be changed with the joint 946. The direction of an image on the display portion 943 may be changed and display and non-display of an image may be switched depending on the angle between the housings 941 and 942. A wireless IC may be incorporated in the video camera 940. This makes it possible to, for example, wirelessly transmit obtained data or wirelessly operate the video camera 940.

FIG. 12E illustrates an example of a bangle-type information terminal. An information terminal 950 includes a housing 951 and a display portion 952. Since the display portion 952 is supported by the housing 951 having a curved surface, a display surface of the display portion 952 is curved. Thus, a flexible substrate is preferably used as a display panel of the display portion 952. Since the display portion 952 includes a touch sensor, operation can be performed by touching the screen with a finger or the like. The information terminal 950, which includes a wireless IC, is capable of transmitting and receiving data wirelessly. The information terminal 950 may include an imaging device to have an imaging function.

FIG. 12F illustrates an example of a watch-type information terminal. An information terminal 960 includes a housing 961, a display portion 962, a band 963, a buckle 964, an operation button 965, an input/output terminal 966, and the like. The information terminal 960, which includes a wireless IC, is capable of transmitting and receiving data wirelessly. The information terminal 960 is capable of executing a variety of applications such as mobile phone calls, e-mailing, viewing and editing texts, music reproduction, Internet communication, and computer games.

The display surface of the display portion 962 is curved, and images can be displayed on the curved display surface. Thus, a flexible substrate is preferably used as a display panel of the display portion 962. Since the display portion 962 includes a touch sensor, operation can be performed by touching the screen with a finger, a stylus, or the like. For example, by touching an icon 967 displayed on the display portion 962, an application can be started. With the operation button 965, a variety of functions such as time setting, power on/off, on/off of wireless communication, setting and cancellation of silent mode, and setting and cancellation of power saving mode can be performed. For example, the functions of the operation button 965 can be set by setting the operating system incorporated in the information terminal 960.

The information terminal 960, which includes a wireless IC, is capable of employing near field communication that is a communication method based on an existing communication standard. For example, mutual communication between the information terminal 960 and a headset capable of wireless communication can be performed, and thus hands-free calling is possible. Moreover, the information terminal 960 includes the input/output terminal 966, and data can be directly transmitted to and received from another information terminal via a connector. Power charging through the input/output terminal 966 is possible. Note that charging may be performed by wireless power feeding without using the input/output terminal 966.

FIG. 12G illustrates an electric refrigerator-freezer as an example of a home electric appliance. An electric refrigerator-freezer 970 includes a housing 971, a refrigerator door 972, a freezer door 973, and the like.

FIG. 12H illustrates a structure example of a motor vehicle. A motor vehicle 980 includes a car body 981, wheels 982, a dashboard 983, lights 984, and the like.

As mentioned above, embodiments of the present invention are described in this embodiment and Embodiments 2 and 3 described later, and are not limited to the descriptions of this embodiment and Embodiments 2 and 3. That is, since various embodiments of the present invention are described in this specification and the like, one embodiment of the present invention is not limited to a specific embodiment. Although an example in which the active layer (channel region) of the transistor includes an oxide semiconductor is shown as one embodiment of the present invention, the one embodiment of the present invention is not limited thereto. Depending on the circumstances and conditions, the transistor of one embodiment of the present invention may include a variety of semiconductors. Depending on the circumstances and conditions, the transistor of one embodiment of the present invention may include, for example, at least one of silicon, germanium, silicon germanium, silicon carbide, gallium arsenide, aluminum gallium arsenide, indium phosphide, gallium nitride, an organic semiconductor, and the like. Depending on the circumstances and conditions, the transistor of one embodiment of the present invention does not necessarily include an oxide semiconductor, for example. Although the oscillator circuit includes the MEMS switch in one embodiment of the present invention, the one embodiment of the present invention is not limited thereto. Depending on the circumstances and conditions, the oscillator circuit of one embodiment of the present invention may include a variety of circuits or switches. Depending on the circumstances and conditions, the oscillator circuit does not necessarily include the MEMS switch in one embodiment of the present invention, for example.

### Embodiment 2

In this embodiment, an OS transistor and a semiconductor device including an OS transistor are described.

### <<Structure Example 1 of OS Transistor>>

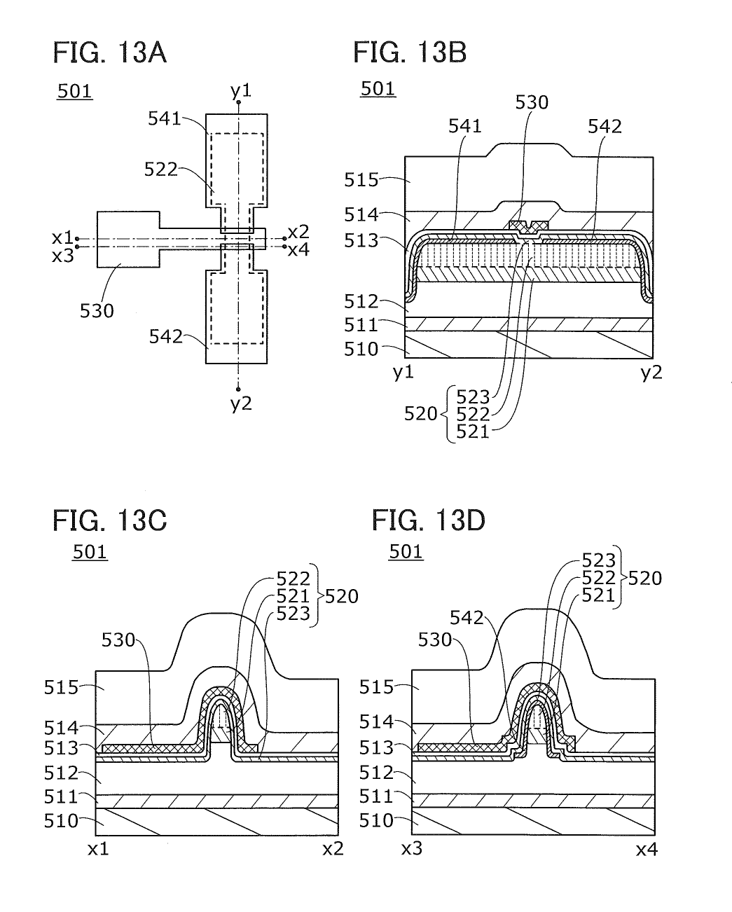

FIGS. 13A to 13D illustrate a structure example of an OS transistor. FIG. 13A is a top view illustrating the structure example of the OS transistor. FIG. 13B is a cross-sectional view taken along line y1-y2, FIG. 13C is a cross-sectional view taken along line x1-x2, and FIG. 13D is a cross-sectional view taken along line x3-x4. Here, in some cases, the direction of the line y1-y2 is referred to as a channel length direction, and the direction of the line x1-x2 is referred to as a channel width direction. Accordingly, FIG. 13B illustrates a cross-sectional structure of the OS transistor in the channel length direction, and FIGS. 13C and 13D each illustrate a cross-sectional structure of the OS transistor in the channel width direction. Note that to clarify the device structure, FIG. 13A does not illustrate some components.

An OS transistor 501 is formed over an insulating surface, here, over an insulating layer 511. The insulating layer 511 is formed over a surface of a substrate 510. The OS transistor 501 is covered with an insulating layer 514 and an insulating layer 515. Note that the insulating layers 514 and 515 may be regarded as components of the OS transistor 501. The OS transistor 501 includes an insulating layer 512, an insulating layer 513, oxide semiconductor (OS) layers 521 to 523, a conductive layer 530, a conductive layer 541, and a conductive layer 542. The insulating layer 513 includes a region functioning as a gate insulating layer. The conductive layer 530 functions as a gate electrode. Here, the OS layers 521, 522, and 523 are collectively referred to as an OS layer 520.

As illustrated in FIGS. 13B and 13C, the OS layer 520 includes a region where the OS layer 521, the OS layer 522, and the OS layer 523 are stacked in this order. The insulating layer 513 covers this stacked region. The conductive layer 530 overlaps the stacked region with the insulating layer 513 positioned therebetween. The conductive layer 541 and the conductive layer 542 are provided over the stacked film formed of the OS layer 521 and the OS layer 523 and are in contact with a top surface of this stacked film and a side surface positioned in the channel length direction of the stacked film. In the example of FIGS. 13A to 13D, the conductive layers 541 and 542 are also in contact with the insulating layer 512. The OS layer 523 is formed to cover the OS layers 521 and 522 and the conductive layers 541 and 542. A bottom surface of the OS layer 523 is in contact with a top surface of the OS layer 522.

The conductive layer 530 is formed so as to surround, in the channel width direction, the region where the OS layers 521 to 523 are stacked in the OS layer 520 with the insulating layer 513 positioned therebetween (see FIG. 13C). Therefore, a gate electric field in the vertical direction and a gate electric field in the lateral direction are applied to this stacked region. In the OS transistor 501, the “gate electric field” refers to an electric field generated by voltage applied to the conductive layer 530 (gate electrode layer). Accordingly, the whole stacked region of the OS layers 521 to 523 can be electrically surrounded by the gate electric fields, so that a channel is formed in the whole OS layer 522 (bulk), in some cases. Thus, high on-state current of the OS transistor 501 can be achieved.

In this specification, a structure of a transistor in which a semiconductor is electrically surrounded by a gate electric field as in the above transistor is referred to as a surrounded channel (s-channel) structure. The OS transistor 501 has the s-channel structure. With this s-channel structure, a large amount of current can flow between the source and the drain of the transistor, so that a high drain current in an on state (on-state current) can be achieved.

By employing the s-channel structure in the OS transistor 501, channel formation region controllability by a gate electric field applied to the side surface of the OS layer 522 becomes easy. In the structure where the conductive layer 530 reaches below the OS layer 522 and faces the side surface of the OS layer 521, higher controllability can be achieved, which is preferable. Consequently, the subthreshold swing (S value) of the OS transistor 501 can be made small, so that a short-channel effect can be reduced. Therefore, this is suitable for miniaturization.

The s-channel structure, because of its high on-state current, is suitable for a semiconductor device such as large-scale integration (LSI) which requires a miniaturized transistor. Since high on-state current can be obtained, the s-channel structure is suitable for a transistor that needs to have high driving frequency. A semiconductor device including the miniaturized transistor can have a high integration degree and high density. The OS transistor preferably has, for example, a region where a channel length is greater than or equal to 10 nm and less than 1 μm, further preferably greater than or equal to 10 nm and less than 100 nm, still further preferably greater than or equal to 10 nm and less than 60 nm, and yet still further preferably greater than or equal to 10 nm and less than 30 nm.

In addition, the s-channel structure is suitable for a power control transistor because of its high on-state current. To employ the s-channel structure in the power control transistor that requires a high withstand voltage, the channel length is preferably long. For example, the OS transistor preferably has a region where the channel length is greater than or equal to 1 μm, further preferably greater than or equal to 10 μm, and still further preferably greater than or equal to 100 μm.

A conductor functioning as a gate of a transistor is referred to as a gate electrode. A conductor functioning as a source of a transistor is referred to as a source electrode. A conductor functioning as a drain of a transistor is referred to as a drain electrode. A region functioning as a source of a transistor is referred to as a source region. A region functioning as a drain of a transistor is referred to as a drain region. In this specification, a gate electrode is referred to as a gate, a drain electrode or a drain region is referred to as a drain, and a source electrode or a source region is referred to as a source in some cases.

The channel length refers to, for example, a distance between a source and a drain in a region where a semiconductor (or a portion where a current flows in a semiconductor when a transistor is on) and a gate overlap each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

A channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is high in some cases. In that case, an effective channel width obtained when a channel is actually formed is greater than an apparent channel width shown in the top view.

In a transistor having a three-dimensional structure, an effective channel width is difficult to measure in some cases. For example, estimation of an effective channel width from a design value requires an assumption that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, the values may be different from those calculated using an effective channel width in some cases.

### <Substrate>

The substrate 510 is not limited to a simple supporting substrate and may be a substrate where a device such as a transistor is formed. In that case, one of the conductive layers 530, 541, and 542 of the OS transistor 501 may be electrically connected to the device.

### <Base Insulating Layer>

The insulating layer 511 has a function of preventing impurity diffusion from the substrate 510. The insulating layer 512 preferably has a function of supplying oxygen to the OS layer 520. For this reason, the insulating layer 512 is preferably an insulating film containing oxygen, more preferably, an insulating film containing oxygen in which the oxygen content is higher than that in the stoichiometric composition. For example, a film from which oxygen molecules at more than or equal to 1.0×10¹⁸ molecules/cm³ are released in thermal desorption spectroscopy (TDS) at a surface temperature of the film of higher than or equal to 100° C. and lower than or equal to 700° C., or higher than or equal to 100° C. and lower than or equal to 500° C. can be used. When the substrate 510 is a substrate where a device is formed as described above, the insulating layer 511 is preferably subjected to planarization treatment such as chemical mechanical polishing (CMP) so as to have a flat surface.

The insulating layers 511 and 512 can be formed using an insulating material of aluminum oxide, aluminum oxynitride, magnesium oxide, silicon oxide, silicon oxynitride, gallium oxide, germanium oxide, yttrium oxide, zirconium oxide, lanthanum oxide, neodymium oxide, hafnium oxide, tantalum oxide, silicon nitride, silicon nitride oxide, aluminum nitride oxide, or the like, or a mixed material of these materials.

### <Gate Electrode>

The conductive layer 530 is preferably formed using a low resistance material such as copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), iridium (Ir), strontium (Sr), and platinum (Pt); an alloy containing any of these materials; or a compound containing any of these materials as its main component.

The conductive layer 530 may have a single-layer structure or a stacked-layer structure of two or more layers. For example, any of the following structures can be employed: a single-layer structure of an aluminum film containing silicon; a two-layer structure in which a titanium film is stacked over an aluminum film; a two-layer structure in which a titanium film is stacked over a titanium nitride film; a two-layer structure in which a tungsten film is stacked over a titanium nitride film; a two-layer structure in which a tungsten film is stacked over a tantalum nitride film or a tungsten nitride film; a three-layer structure in which a titanium film, an aluminum film, and a titanium film are stacked in this order; a single-layer structure of a Cu—Mn alloy film; a two-layer structure in which a Cu film is stacked over a Cu—Mn alloy film; and a three-layer structure in which a Cu—Mn alloy film, a Cu film, and a Cu—Mn alloy film are stacked in this order. A Cu—Mn alloy film is preferably used because of its low electrical resistance and because it forms manganese oxide at the interface with an insulating film containing oxygen and manganese oxide can prevent Cu diffusion.

The conductive layer 530 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

### <Gate Insulating Layer>

The insulating layer 513 is formed using an insulating film having a single-layer structure or a layered structure. The insulating layer 513 can be formed using an insulating film containing at least one of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. The insulating layer 513 may be a stack including any of the above materials. The insulating layer 513 may contain lanthanum (La), nitrogen, zirconium (Zr), or the like as an impurity. The insulating layer 511 can be formed in a manner similar to that of the insulating layer 513. The insulating layer 511 contains oxygen, nitrogen, silicon, hafnium, or the like, for example. Specifically, the insulating layer 511 preferably contains hafnium oxide, and silicon oxide or silicon oxynitride.

Hafnium oxide has a higher dielectric constant than silicon oxide and silicon oxynitride. Therefore, the insulating layer 513 using hafnium oxide can have a larger thickness than the insulating layer 513 using silicon oxide, so that leakage current due to tunnel current can be reduced. That is, a transistor with low off-state current can be provided. Moreover, hafnium oxide with a crystal structure has a higher dielectric constant than hafnium oxide with an amorphous structure. Therefore, it is preferable to use hafnium oxide with a crystal structure in order to provide a transistor with low off-state current. Examples of the crystal structure include a monoclinic crystal structure and a cubic crystal structure. Note that one embodiment of the present invention is not limited to the above examples.

### <Source Electrode, Drain Electrode, Back Gate Electrode>

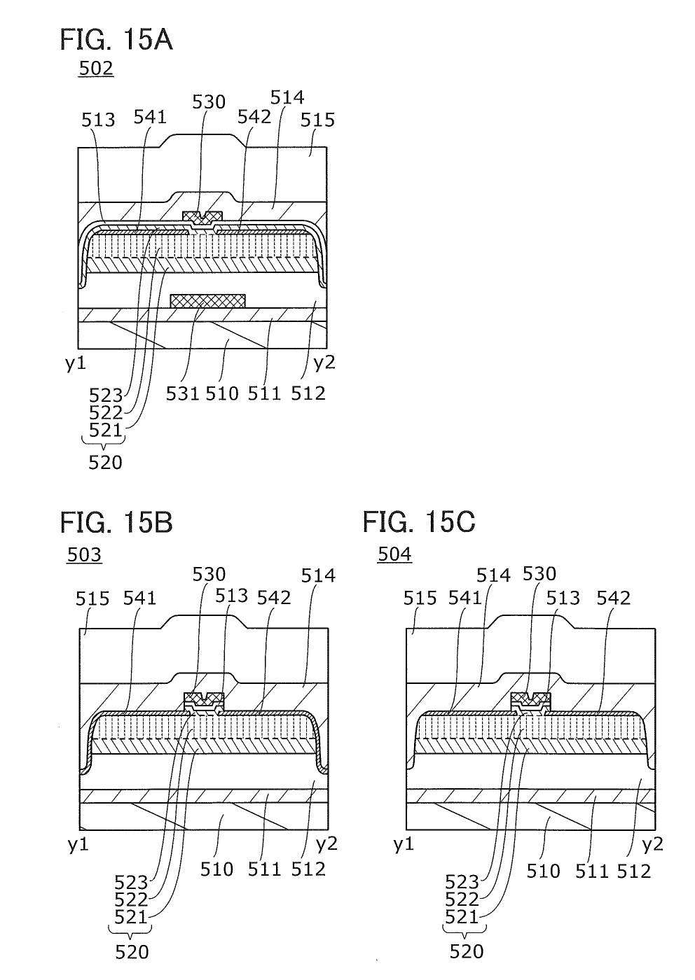

The conductive layers 541 and 542 can be formed in a manner similar to that of the conductive layer 530. A Cu—Mn alloy film is preferably used for the conductive layers 541 and 542 because of its low electrical resistance, because it forms manganese oxide at the interface with an oxide semiconductor film when formed in contact with the oxide semiconductor film, and because manganese oxide can prevent Cu diffusion. Furthermore, a conductive layer 531 described later (see FIG. 15A) can be formed in a manner similar to that of the conductive layer 530.

### <Protective Insulating Film>

The insulating layer 514 preferably has a function of blocking oxygen, hydrogen, water, an alkali metal, an alkaline earth metal, and the like. The insulating layer 514 can prevent outward diffusion of oxygen from the OS layer 520 and entry of hydrogen, water, or the like into the OS layer 520 from the outside. The insulating layer 514 can be a nitride insulating film, for example. The nitride insulating film is formed using silicon nitride, silicon nitride oxide, aluminum nitride, aluminum nitride oxide, or the like. Note that instead of the nitride insulating film having a blocking effect against oxygen, hydrogen, water, an alkali metal, an alkaline earth metal, and the like, an oxide insulating film having a blocking effect against oxygen, hydrogen, water, and the like may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be used.

An aluminum oxide film is preferably used as the insulating layer 514 because it is highly effective in preventing transmission of both oxygen and impurities such as hydrogen and moisture. Thus, during and after the manufacturing process of the transistor, the aluminum oxide film can suitably function as a protective film that has effects of preventing entry of impurities such as hydrogen and moisture, which cause variations in the electrical characteristics of the transistor, into the OS layer 520, preventing release of oxygen, which is the main component of the OS layer 520, from the oxide semiconductor, or preventing unnecessary release of oxygen from the insulating layer 512, for example. In addition, oxygen contained in the aluminum oxide film can be diffused into the oxide semiconductor.

### <Interlayer Insulating Film>

The insulating layer 515 is preferably formed over the insulating layer 514. The insulating layer 515 can be formed using an insulating film with a single-layer structure or a stacked-layer structure. The insulating layer can be formed using an insulating film containing one or more of magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

### <Oxide Semiconductor Layer>

As the semiconductor material of the OS layers 521 to 523, typically, an In—Ga oxide, an In—Zn oxide, or an In-M-Zn oxide (M is Ga, Y, Sn, Zr, La, Ce, Nd, or the like) is used. The element M is an element having a high bonding energy with oxygen, for example. Alternatively, the element M is an element whose bonding energy with oxygen is higher than that of indium. The OS layers 521 to 523 are not limited to the oxide layers containing indium. The OS layers 521 to 523 can be formed using a Zn—Sn oxide layer, a Ga—Sn oxide layer, or a Zn—Mg oxide layer, for example. The OS layer 522 is preferably formed using an In-M-Zn oxide. The OS layers 521 and 523 can be formed using a Ga oxide.

The OS layer 522 is not limited to the oxide semiconductor containing indium. The OS layer 522 may be, for example, an oxide semiconductor which does not contain indium and contains zinc, an oxide semiconductor which does not contain indium and contains gallium, or an oxide semiconductor which does not contain indium and contains tin, e.g., a zinc tin oxide or a gallium tin oxide.

For the OS layer 522, an oxide with a wide energy gap may be used. The energy gap of the OS layer 522 is, for example, 2.5 eV or larger and 4.2 eV or smaller, preferably 2.8 eV or larger and 3.8 eV or smaller, further preferably 3 eV or larger and 3.5 eV or smaller.

The OS layer 522 is preferably a CAAC-OS film which will be described later. When the oxide semiconductor contains Zn, the oxide semiconductor is easily to be crystallized, for example. Thus, the OS layer 522 preferably contains Zn.

When an interface level is formed at the interface between the OS layer 522 and the OS layer 521, a channel region is formed also in the vicinity of the interface, which causes a change in the threshold voltage of the OS transistor 501. It is preferable that the OS layer 521 contains at least one of the metal elements contained in the OS layer 522. Accordingly, an interface level is unlikely to be formed at the interface between the OS layer 522 and the OS layer 523, and variations in the electrical characteristics of the OS transistor 501, such as the threshold voltage can be reduced.

The OS layer 523 preferably contains at least one of the metal elements contained in the OS layer 522 because interface scattering is unlikely to occur at the interface between the OS layer 522 and the OS layer 523, and carrier transfer is not inhibited. Thus, the field-effect mobility of the OS transistor 501 can be increased.

The OS layers 521, 522, and 523 preferably include at least Indium. In the case of using an In-M-Zn oxide as the OS layer 521, when the summation of In and M is assumed to be 100 atomic %, the proportions of In and M are preferably set to be less than 50 atomic % and greater than 50 atomic %, respectively, further preferably less than 25 atomic % and greater than 75 atomic %, respectively. In the case of using an In-M-Zn oxide as the OS layer 522, when the summation of In and M is assumed to be 100 atomic %, the proportions of In and M are preferably set to be greater than 25 atomic % and less than 75 atomic %, respectively, further preferably greater than 34 atomic % and less than 66 atomic %, respectively. In the case of using an In-M-Zn oxide as the OS layer 523, when the summation of In and M is assumed to be 100 atomic %, the proportions of In and M are preferably set to be less than 50 atomic % and greater than 50 atomic %, respectively, further preferably less than 25 atomic % and greater than 75 atomic %, respectively. Note that the OS layer 523 may be an oxide that is the same type as that of the OS layer 521. Note that the OS layer 521 and/or the OS layer 523 do/does not necessarily contain indium in some cases. For example, the OS layer 521 and/or the OS layer 523 can be formed using a gallium oxide film.

It is preferable that the OS layer 522 have the highest carrier mobility among the OS layers 521 to 523. Accordingly, a channel can be formed in the OS layer 522 that is apart from the insulating layer 511.

In an oxide containing In such as an In-M-Zn oxide, carrier mobility can be increase by an increase in the In content. In the In-M-Zn oxide, the s orbital of heavy metal mainly contributes to carrier transfer, and when the indium content in the oxide semiconductor is increased, overlaps of the s orbitals of In atoms are increased; therefore, an oxide having a high content of indium has higher mobility than an oxide having a low content of indium. Therefore, an oxide having a high content of indium is used as an oxide semiconductor film, whereby carrier mobility can be increased.

When an oxide semiconductor film is deposited by a sputtering method, because of heating of a substrate surface (the surface on which the CAAC-OS is deposited), space heating, or the like, the composition of the film is sometimes different from that of a target as a source or the like. For example, in the case of using a target of an In—Ga—Zn oxide, since zinc oxide sublimates more easily than indium oxide, gallium oxide, or the like, the source and the In—Ga—Zn oxide are likely to have different compositions. Specifically, the content of Zn is smaller than that of the source in the In—Ga—Zn oxide. Thus, the source is preferably selected taking into account the change in composition. Note that a difference between the compositions of the source and the film is also affected by a pressure or a gas used for the deposition as well as a temperature.

In the case where the OS layer 522 is an In-M-Zn oxide formed by a sputtering method, it is preferable that the atomic ratio of metal elements of a target used for depositing the In-M-Zn oxide be In:M:Zn=1:1:1, 3:1:2, or 4:2:4.1. For example, the atomic ratio of metal elements contained in a semiconductor film deposited using a target of In:M:Zn=4:2:4.1 is approximately In:M:Zn=4:2:3.

In the case where each of the OS layers 521 and 523 is an In-M-Zn oxide formed by a sputtering method, it is preferable that the atomic ratio of metal elements of a target used for depositing the In-M-Zn oxide be In:M:Zn=1:3:2 or 1:3:4.

In the case where the oxide semiconductor film is formed by a sputtering method, a power supply device for generating plasma can be an RF power supply device, an AC power supply device, a DC power supply device, or the like as appropriate. As a sputtering gas, a rare gas (typically argon), oxygen gas, or a mixed gas of a rare gas and oxygen gas is used as appropriate. In the case of using the mixed gas of a rare gas and oxygen gas, the proportion of oxygen gas to a rare gas is preferably increased. Furthermore, a target may be appropriately selected in accordance with the composition of the oxide semiconductor to be formed.

To make the oxide semiconductor intrinsic or substantially intrinsic, besides the high vacuum evacuation of the chamber, a highly purification of a sputtering gas is also needed. As an oxygen gas or an argon gas used for a sputtering gas, a gas which is highly purified to have a dew point of −40° C. or lower, preferably −80° C. or lower, further preferably −100° C. or lower, still further preferably −120° C. or lower is used, whereby entry of moisture or the like into the oxide semiconductor can be prevented as much as possible.

### <Energy Band Structure>

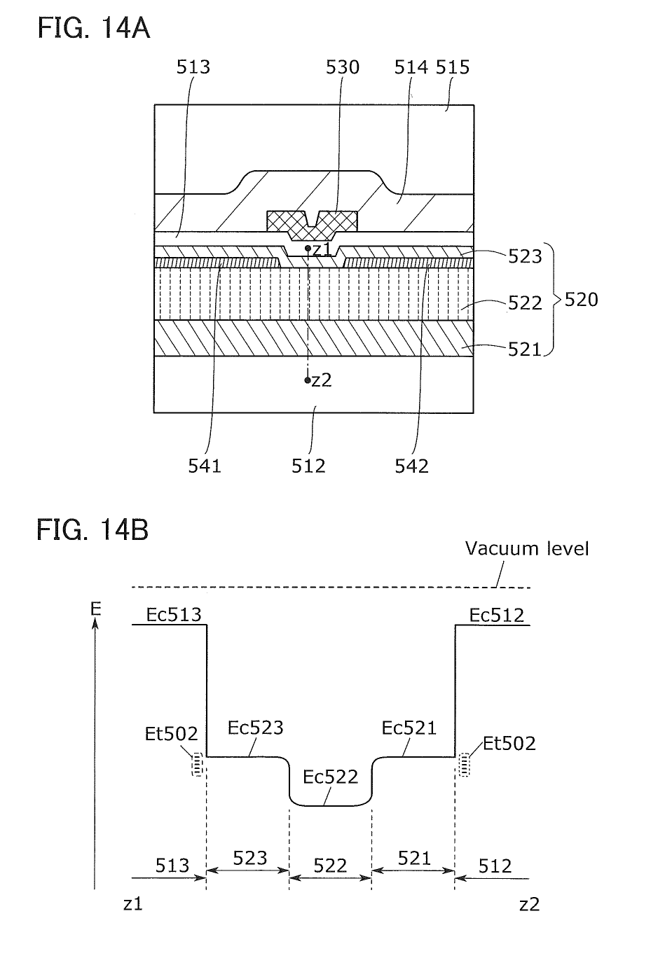

Next, the function and effect of the OS layer 520 in which the OS layers 521, 522, and 523 are stacked are described using an energy band diagram in FIG. 14B. FIG. 14A is an enlarged view of a channel region of the OS transistor 501 in FIG. 13B. FIG. 14B shows an energy band diagram of a portion taken along dotted line z1-z2 (the channel formation region of the OS transistor 501) in FIG. 14A. The OS transistor 501 is described below as an example, but the same applies to the OS transistors 502 to 506.

In FIG. 14B, Ec512, Ec521, Ec522, Ec523, and Ec513 indicate the energy at the conduction band minimum of the insulating layer 512, the OS layer 521, the OS layer 522, the OS layer 523, and the insulating layer 513, respectively.

Here, a difference in energy between the vacuum level and the conduction band minimum (the difference is also referred to as electron affinity) corresponds to a value obtained by subtracting an energy gap from a difference in energy between the vacuum level and the valence band maximum (the difference is also referred to as an ionization potential). The energy gap can be measured using a spectroscopic ellipsometer (UT-300 manufactured by HORIBA JOBIN YVON S.A.S.). The energy difference between the vacuum level and the valence band maximum can be measured using an ultraviolet photoelectron spectroscopy (UPS) device (VersaProbe manufactured by ULVAC-PHI, Inc.).

Since the insulating layer 512 and the insulating layer 513 are insulators, Ec512 and Ec513 are closer to the vacuum level than Ec521, Ec522, and Ec523 (i.e., the insulating layer 512 and the insulating layer 513 have a smaller electron affinity than the OS layers 521, 522, and 523).

The OS layer 522 is an oxide layer which has a larger electron affinity than the OS layers 521 and 523. For example, as the OS layer 522, an oxide having higher electron affinity than those of the OS layer 521 and the OS layer 523 by greater than or equal to 0.07 eV and less than or equal to 1.3 eV, preferably greater than or equal to 0.1 eV and less than or equal to 0.7 eV, further preferably greater than or equal to 0.15 eV and less than or equal to 0.4 eV is used. Note that the electron affinity refers to an energy gap between the vacuum level and the conduction band minimum.

When voltage is applied to the gate (the conductive layer 530) of the OS transistor 501, a channel is formed in the OS layer 522 having the highest electron affinity among the OS layers 521, 522, and 523.

An indium gallium oxide has small electron affinity and a high oxygen-blocking property. Therefore, the OS layer 523 preferably contains an indium gallium oxide. The gallium atomic ratio [Ga/(In+Ga)] is, for example, higher than or equal to 70%, preferably higher than or equal to 80%, further preferably higher than or equal to 90%.

Ec521 is closer to the vacuum level than Ec522. Specifically, Ec521 is preferably located closer to the vacuum level than Ec522 by 0.05 eV or more, 0.07 eV or more, 0.1 eV or more, or 0.15 eV or more and 2 eV or less, 1 eV or less, 0.5 eV or less, or 0.4 eV or less.

Ec523 is closer to the vacuum level than Ec522. Specifically, Ec523 is preferably located closer to the vacuum level than Ec522 by 0.05 eV or more, 0.07 eV or more, 0.1 eV or more, or 0.15 eV or more and 2 eV or less, 1 eV or less, 0.5 eV or less, or 0.4 eV or less.

In some cases, there is a mixed region of the OS layer 521 and the OS layer 522 between the OS layer 521 and OS layer 522. Furthermore, in some cases, there is a mixed region of the OS layer 523 and the OS layer 522 between the OS layer 523 and OS layer 522. Because the mixed region has a low interface state density, a stack of the OS layers 521 to 523 (the OS layer 520) has a band structure where energy at each interface and in the vicinity of the interface is changed continuously (continuous junction).

Electrons transfer mainly through the OS layer 522 in the OS layer 520 having such an energy band structure. Therefore, even if an interface state exists at the interface between the OS layer 521 and the insulating layer 512 or the interface between the OS layer 523 and the insulating layer 513, electron movement in the OS layer 520 is less likely to be inhibited and the on-sale current of the OS transistor 501 can be increased.

Although trap states Et502 due to impurities or defects might be formed in the vicinity of the interface between the OS layer 521 and the insulating layer 512 and the interface between the OS layer 523 and the insulating layer 513 as illustrated in FIG. 14B, the OS layer 522 can be separated from the trap states Et502 owing to the existence of the OS layers 521 and 523. In the transistor 501, in the channel width direction, the top surface and side surfaces of the OS layer 522 are in contact with the OS layer 523, and the bottom surface of the OS layer 522 is in contact with the OS layer 521 (see FIG. 13C). Surrounding the OS layer 522 by the OS layers 521 and 523 in this manner can further reduce the influence of the trap states Et502.

However, when the energy difference between Ec522 and Ec521 or Ec523 is small, an electron in the OS layer 522 might reach the trap state by passing over the energy difference. Since the electron is trapped in the trap level, negative fixed electric charge is caused at the interface with the insulating film; thus, the threshold voltage of the transistor is shifted in a positive direction. Therefore, each of the energy gaps between Ec521 and Ec522 and between Ec522 and Ec523 is preferably 0.1 eV or more, or further preferably 0.15 eV or more, in which case a change in the threshold voltage of the OS transistor 501 can be reduced and the OS transistor 501 can have favorable electrical characteristics.

As factors of inhibiting electron movement are decreased, the on-state current of the transistor can be increased. For example, in the case where there is no factor of inhibiting electron movement, electrons are assumed to be moved efficiently. Electron movement is inhibited, for example, in the case where physical unevenness in the channel formation region is large. The electron movement is also inhibited, for example, in the case where the density of defect states is high in a region where a channel is formed.

To increase the on-state current of the OS transistor 501, for example, root mean square (RMS) roughness with a measurement area of 1 μm×1 μm of a top surface or a bottom surface of the OS layer 522 (a formation surface; here, the OS layer 521) is less than 1 nm, preferably less than 0.6 nm, further preferably less than 0.5 nm, still further preferably less than 0.4 nm. The average surface roughness (also referred to as Ra) with the measurement area of 1 μm×1 μm is less than 1 nm, preferably less than 0.6 nm, further preferably less than 0.5 nm, still further preferably less than 0.4 nm. The maximum difference (P-V) with the measurement area of 1 μm×1 μm is less than 10 nm, preferably less than 9 nm, further preferably less than 8 nm, still further preferably less than 7 nm.

For example, in the case where the OS layer 522 contains oxygen vacancies (also denoted by Vₒ), donor levels are formed by entry of hydrogen into sites of oxygen vacancies in some cases. A state in which hydrogen enters sites of oxygen vacancies is denoted by VₒH in the following description in some cases. VₒH is a factor of decreasing the on-state current of the transistor because VₒH scatters electrons. Note that sites of oxygen vacancies become more stable by entry of oxygen than by entry of hydrogen. Thus, by decreasing oxygen vacancies in the OS layer 522, the on-state current of the transistor can be increased in some cases. For example, the hydrogen concentration at a certain depth in the OS layer 522 or in a certain region of the OS layer 522, which is measured by secondary ion mass spectrometry (SIMS), can be lower than or equal to 2×10²⁰ atoms/cm³, lower than or equal to 5×10¹⁹ atoms/cm³, or lower than or equal to 1×10¹⁹ atoms/cm³. The hydrogen concentration is preferably as low as possible, and the hydrogen concentration in a certain region of the OS layer 522, which is measured by SIMS, is preferably lower than 1×10¹⁵ atoms/cm³, further preferably lower than a lower measurement limit.

To decrease oxygen vacancies in the OS layer 522, for example, there is a method in which excess oxygen in the insulating layer 512 is moved to the OS layer 522 through the OS layer 521. In this case, the OS layer 521 is preferably a layer having an oxygen-transmitting property (a layer through which oxygen passes or is transmitted).

In the case where the OS transistor 501 has an s-channel structure, a channel can be formed in the whole OS layer 522. The thickness of the OS layer 522 may be greater than or equal to 10 nm and less than or equal to 100 nm, or greater than or equal to 10 nm and less than or equal to 30 nm.

Moreover, the thickness of the OS layer 523 is preferably small to increase the on-state current of the transistor. The thickness of the OS layer 523 is less than 10 nm, preferably less than or equal to 5 nm, or further preferably less than or equal to 3 nm, for example. Meanwhile, the OS layer 523 has a function of blocking entry of elements other than oxygen (such as hydrogen and silicon) included in the adjacent insulator into the OS layer 522. For example, the OS layer 523 has a region with a thickness of greater than or equal to 0.3 nm, preferably greater than or equal to 1 nm, more preferably greater than or equal to 2 nm. The OS layer 523 preferably has an oxygen blocking property to suppress outward diffusion of oxygen released from the insulating layer 512 and the like.

To improve reliability, preferably, the thickness of the OS layer 521 is large and the thickness of the OS layer 523 is small. For example, the OS layer 521 has a region with a thickness of, for example, greater than or equal to 10 nm, preferably greater than or equal to 20 nm, further preferably greater than or equal to 40 nm, still further preferably greater than or equal to 60 nm. When the thickness of the OS layer 521 is made large, a distance from an interface between the adjacent insulator and the OS layer 521 to the OS layer 522 in which a channel is formed can be large. Since the productivity of the semiconductor device might be decreased, the OS layer 521 has a region with a thickness of, for example, less than or equal to 200 nm, preferably less than or equal to 120 nm, further preferably less than or equal to 80 nm.

In order that an OS transistor in which a channel is formed in an oxide semiconductor have stable electrical characteristics, it is effective to make the oxide semiconductor intrinsic or substantially intrinsic by reducing the concentration of impurities in the oxide semiconductor. The term “substantially intrinsic” refers to a state where an oxide semiconductor has a carrier density lower than 1×10¹⁷/cm³, preferably lower than 1×10¹⁵/cm³, more preferably lower than 1×10¹³/cm³.

In the oxide semiconductor, hydrogen, nitrogen, carbon, silicon, and a metal element other than a main component are impurities. For example, hydrogen and nitrogen form donor levels to increase the carrier density, and silicon forms impurity levels in the oxide semiconductor. The impurity levels serve as traps and might cause the electric characteristics of the transistor to deteriorate. Therefore, it is preferable to reduce the concentration of the impurities in the OS layers 521, 522, and 523 and at interfaces between the OS layers.

In order to make the oxide semiconductor intrinsic or substantially intrinsic, for example, the concentration of silicon at a certain depth of the oxide semiconductor or in a region of the oxide semiconductor, which is measured by SIMS, is lower than 1×10¹⁹ atoms/cm³, preferably lower than 5×10¹⁸ atoms/cm³, further preferably lower than 1×10¹⁸ atoms/cm³. The concentration of hydrogen at a certain depth of the oxide semiconductor or in a region of the oxide semiconductor, which is measured by SIMS, is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³. It is preferable that the hydrogen concentration of the oxide semiconductor be as low as possible, and the hydrogen concentration measured by SIMS is preferably lower than 1×10¹⁵ atoms/cm³, further preferably lower than a lower measurement limit. The concentration of nitrogen at a certain depth of the oxide semiconductor or in a region of the oxide semiconductor, which is measured by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

In addition, in the case where the oxide semiconductor includes a crystal, high concentration of silicon or carbon might reduce the crystallinity of the oxide semiconductor. In order not to reduce the crystallinity of the oxide semiconductor, for example, the concentration of silicon at a certain depth of the oxide semiconductor or in a region of the oxide semiconductor is lower than 1×10¹⁹ atoms/cm³, preferably lower than 5×10¹⁸ atoms/cm³, further preferably lower than 1×10¹⁸ atoms/cm³. Furthermore, the concentration of carbon at a certain depth of the oxide semiconductor or in a region of the oxide semiconductor is lower than 1×10¹⁹ atoms/cm³, preferably lower than 5×10¹⁸ atoms/cm³, further preferably lower than 1×10¹⁸ atoms/cm³, for example.

By reduction in the impurity concentration in the above manner, the carrier density of the oxide semiconductor that can be measured by Hall effect measurement can be lower than 1×10¹²/cm³, preferably lower than 8×10¹¹/cm³, further preferably lower than 1×10¹¹/cm³, which is a lower measurement limit, and higher than or equal to 1×10⁻⁹/cm³. That is, the carrier density of the oxide semiconductor can be extremely close to zero.

A transistor in which the above highly purified oxide semiconductor is used for a channel formation region exhibits extremely low off-state current. When voltage between a source and a drain is set at about 0.1 V, 5 V, or 10 V, for example, the off-state current standardized on the channel width of the transistor can be as low as several yoctoamperes per micrometer to several zeptoamperes per micrometer.

FIGS. 13A to 13D show examples in which the OS layer 520 has a three-layer structure; however, the present invention is not limited thereto. For example, the OS layer 520 may have a two-layer structure without the OS layer 521 or the OS layer 523. Alternatively, the OS layer 520 may have a four-layer structure in which any one of the oxide semiconductors described as the OS layers 521, 522 and 523 is provided below or over the OS layer 521 or below or over the OS layer 523. Alternatively, the OS layer 520 may have an n-layer structure (11 is an integer of 5 or more) in which any one of the oxide semiconductors (e.g., the OS layers 521 to 523) is provided at two or more of the following positions: between arbitrary layers in the OS layer 520, over the OS layer 520, and below the OS layer 520.

### <<Structure Example 2 of OS Transistor>>

The OS transistor 502 in FIG. 15A is a modification example of the OS transistor 501. Like the OS transistor 501, the OS transistor 502 illustrated also has an s-channel structure. The OS transistor 502 is different from the OS transistor 501 in the shapes of the conductive layers 541 and 542 and in that the conductive layer 531 is provided over the insulating layer 511.

The conductive layer 531 functions as a back gate electrode. A constant potential, the same potential or signal supplied to the conductive layer 530, or a potential or signal that is different from that supplied to the conductive layer 530 may be supplied to the conductive layer 531. The conductive layer 541 and the conductive layer 542 function as a source electrode and a drain electrode.

The conductive layer 541 and the conductive layer 542 in the OS transistor 502 are formed from a hard mask used for forming the stacked film of the OS layer 521 and the OS layer 522. Therefore, the conductive layer 541 and the conductive layer 542 do not have regions in contact with the side surfaces of the OS layer 521 and the OS layer 522. For example, through the following steps, the OS layers 521 and 522 and the conductive layers 541 and 542 can be formed. A two-layer oxide semiconductor film including the OS layers 521 and 522 is formed. A single-layer or multi-layer conductive film is formed over the oxide semiconductor film. This conductive film is etched, so that a hard mask is formed. Using this hard mask, the two-layer oxide semiconductor film is etched to form the OS layers 521 and 522. Then, the hard mask is etched to form the conductive layer 541 and the conductive layer 542.

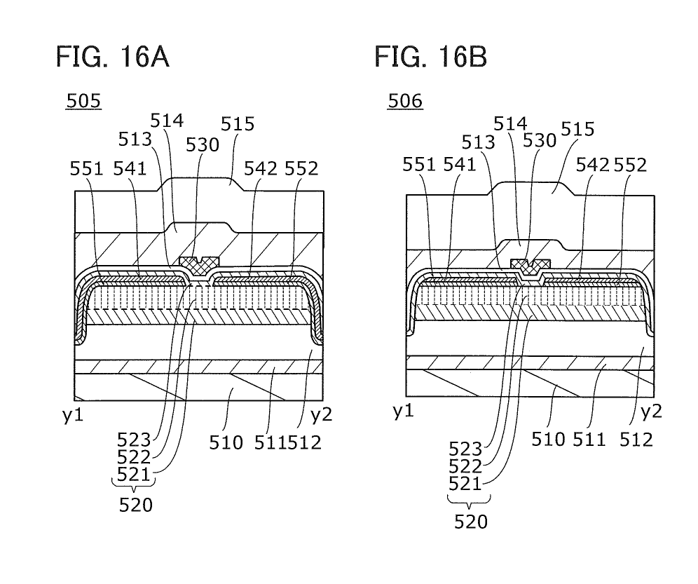

The conductive layer 531 can function as a back gate electrode of the OS transistor 502. The conductive layer 531 can be provided in the OS transistor 501 in FIGS. 13A to 13D, and OS transistors 503 to 506 (FIGS. 15B to 15C, and FIGS. 16A and 16B) which are described later.

### <<Structure Examples 3 and 4 of OS Transistor>>

An OS transistor 503 illustrated in FIG. 15B is a modification example of the OS transistor 501, and an OS transistor 504 illustrated in FIG. 15C is a modification example of the OS transistor 502. In each of the OS transistors 503 and 504, the OS layer 523 and the insulating layer 513 are etched using the conductive layer 530 as a mask. Thus, an edge of the OS layer 523 and an edge of the insulating layer 513 are substantially aligned with an edge of the conductive layer 530.

### <Structure Examples 5 and 6 of OS Transistor>

An OS transistor 505 illustrated in FIG. 16A is a modification example of the OS transistor 501, and an OS transistor 506 illustrated in FIG. 16B is a modification example of the OS transistor 502. The OS transistor 505 has a layer 551 between the OS layer 522 and the conductive layer 541. The OS transistor 506 has a layer 552 between the OS layer 522 and the conductive layer 542.

The layers 551 and 552 can each be formed using a layer of a transparent conductor, an oxide semiconductor, a nitride semiconductor, or an oxynitride semiconductor, for example. The layers 551 and 552 can be formed using an n-type oxide semiconductor layer or can be formed using a conductive layer that has higher resistance than the conductive layers 541 and 542. The layers 551 and 552 may be formed using, for example, any of a layer containing indium, tin, and oxygen, a layer containing indium and zinc, a layer containing indium, tungsten, and zinc, a layer containing tin and zinc, a layer containing zinc and gallium, a layer containing zinc and aluminum, a layer containing zinc and fluorine, a layer containing zinc and boron, a layer containing tin and antimony, a layer containing tin and fluorine, a layer containing titanium and niobium, and the like. Any of these layers may contain one or more of hydrogen, carbon, nitrogen, silicon, germanium, and argon.

The layers 551 and 552 may have a property of transmitting visible light. Alternatively, the layers 551 and 552 may have a property of not transmitting visible light, ultraviolet light, infrared light, or X-rays by reflecting or absorbing it. In some cases, such a property can suppress a change in electrical characteristics of the transistor due to stray light.

The layers 551 and 552 are preferably formed using a layer that does not form a Schottky barrier with the OS layer 522. Thus, on-state characteristics of the OS transistors 505 and 506 can be improved.

Note that the layers 551 and 552 preferably have higher resistance than the conductive layers 541 and 542. The layers 551 and 552 each preferably have resistance lower than the channel resistances of the OS transistors 505 and 506. For example, the layers 551 and 552 may have a resistivity higher than or equal to 0.1 Ωcm and lower than or equal to 100 Ωcm, higher than or equal to 0.5 Ωcm and lower than or equal to 50 Ωcm, or higher than or equal to 1 Ωcm and lower than or equal to 10 Ωcm.

The layers 551 and 552 having resistivity within the above range can reduce electric field concentration in a boundary portion between the channel and the drain. Therefore, a change in electrical characteristics of the transistor can be suppressed. In addition, a punch-through current generated by an electric field from the drain can be reduced. Thus, a transistor with small channel length can have favorable saturation characteristics. Note that in a circuit configuration where the sources and the drains of the OS transistors 505 and 506 do not interchange during the operation, only one of the layers 551 and 552 (e.g., the layer on the drain side) may be preferably provided.

### <<Device Structure Example 1>>

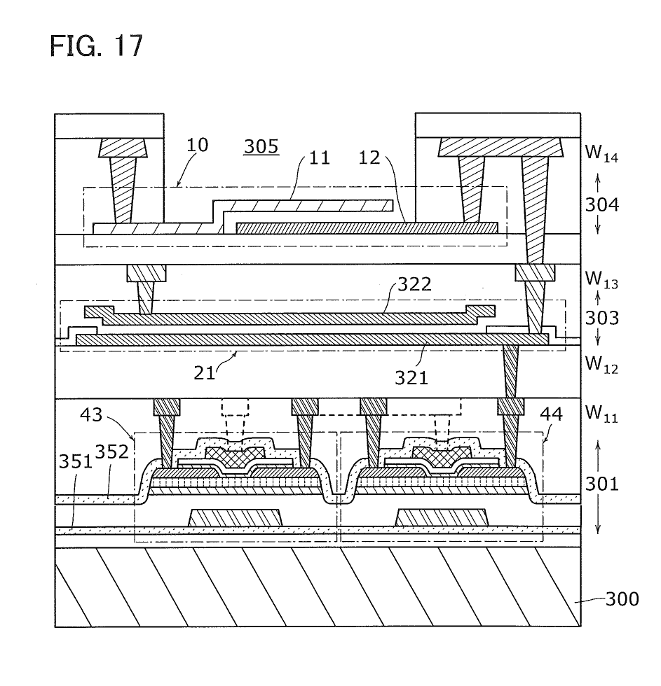

FIG. 17 illustrates an example of the structure of a semiconductor device including OS transistors and a MEMS device. FIG. 17 is a schematic cross-sectional view of the semiconductor device for explaining a stacked-layer structure of the oscillator circuit 101 (FIG. 3A). Thus, the cross-sectional view of FIG. 17 is not the one taken along a certain line in the chip of the oscillator circuit 101. In FIG. 17, an example in which the transistors of the oscillator circuit 101 are OS transistors is shown.

The oscillator circuit 101 is formed over a single crystal silicon wafer 300. An element layer 301 is formed over the single crystal silicon wafer 300. In the element layer 301, the OS transistors are formed. The transistors 43 and 44 are illustrated in FIG. 17. Here, the transistors 43 and 44 each have the same structure as the OS transistor 502 in FIG. 15A.

Wiring layers W₁₁ and W₁₂ are stacked over the element layer 301. The transistors 43 and 44, the capacitor 21, and the wirings WD and WL are electrically connected to one another with the wiring layers W₁₁ and W₁₂. An element layer 303 is stacked over the wiring layer W₁₂. The capacitor 21 is formed in the element layer 303. The capacitor 21 includes a conductive layer 321, a conductive layer 322, and a dielectric which is positioned between them. The capacitor 21 can be formed in the element layer 301. In this case, a first electrode of the capacitor 21 may be formed using a conductive layer which is in the same layer as the gate of the transistor 44, and a second electrode of the capacitor 21 may be formed using the same conductive layer as a first terminal of the transistor 44.

A wiring layer W₁₃, an element layer 304, and a wiring layer W₁₄ are stacked over the element layer 303. In the element layer 304, the MEMS device is formed. Here, the MEMS switch 10 is faulted. In FIG. 17, the MEMS switch 10 is a cantilever type. The structure of the MEMS switch 10 is not limited thereto; for example, a parallel-plate type may be used. A space 305 in the element layer 304 and the wiring layer W₁₄ is formed by a sacrifice layer etching step. The fixed electrode 12 is electrically connected to the capacitor 21 with the wiring layers W₁₃ and W₁₄. The movable electrode 11 is electrically connected to an external terminal (not illustrated) with the wiring layers W₁₃ and W₁₄.

### <<Device Structure Example 2>>

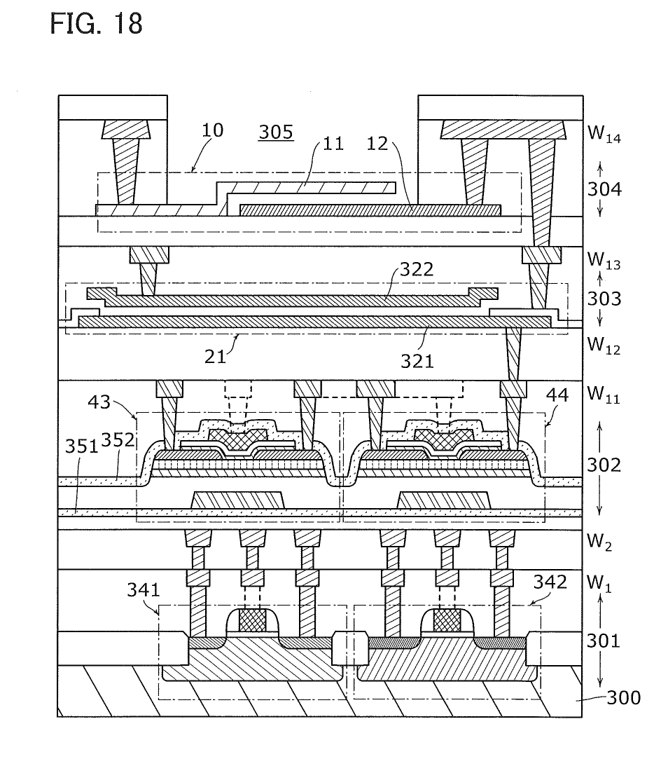

In the case where the buffer circuit 22 is formed using Si transistors or in the case where an oscillator circuit is stacked over a circuit formed using Si transistors which is not a buffer circuit, OS transistors and a MEMS device can be stacked over an element layer where the Si transistors are formed. Such an example is illustrated in FIG. 18.

In a chip in FIG. 18, the element layer 301 is formed over the single crystal silicon wafer 300, and wiring layers W₁ and W₂ are stacked over the element layer 301. An element layer 302 is stacked over the wiring layer W₂. In the element layer 301, the Si transistors are formed; here, a p-channel Si transistor 341 and an n-channel Si transistor 342 are shown as typical examples.

### <<Device Structure Example 3>>

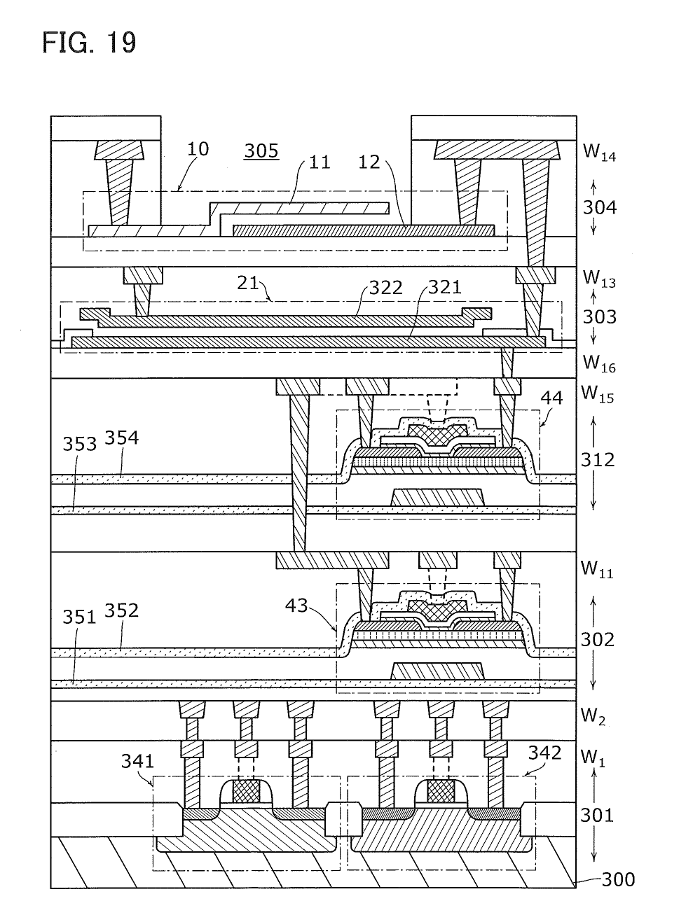

It is possible to stack element layers where OS transistors are formed. Such an example is illustrated in FIG. 19.

In a chip in FIG. 19, an element layer 312 is stacked over the wiring layer W₁₁. In the element layer 312, an OS transistor is formed. Here, the transistor 43 is formed in the element layer 302, and the transistor 44 is formed in the element layer 312. The capacitor 21 may be provided in the element layer 312.

Wiring layers W₁₅ and W₁₆ are stacked over the element layer 312. The transistor 44 is electrically connected to the capacitor 21 and the transistor 43 with the wiring layers W₁₅ and W₁₆.

The electrical characteristics of the OS transistor in the element layer 302 can be different from those of the OS transistor in the element layer 312. As a way to achieve this, for example, the thickness of a gate insulating layer of the OS transistor in the element layer 302 is made different from that of the OS transistor in the element layer 312. The gate insulating layer of the OS transistor in the element layer 312 may be larger than that in the element layer 302. A structure which is suitable for driving the OS transistor in the element layer 312 at a high drain potential may be employed. Alternatively, an oxide semiconductor layer serving as an active layer of the OS transistor in the element layer 302 may be different from that of the OS transistor in the element layer 312. For example, in the case where the oxide semiconductor layer is an In-M-Zn oxide layer (M is Ga, Y, Zr, La, Ce, or Nd), increasing the proportion of the number of indium atoms to that of M atoms can increase the field-effect mobility or improve the current driving capability. Reducing the proportion of the number of indium atoms to that of M atoms can reduce the off-state current.

In the case where the active layer is formed using an In—Ga—Zn oxide deposited by a sputtering method, to manufacture an OS transistor with a lower off-state current, a target with an atomic ratio of In:Ga:Zn=1:1:1 or 1:1:1.2 is used, for example. To manufacture an OS transistor with high current driving capability, a target with an atomic ratio of In:Ga:Zn=3:1:2 or 4:2:4.1 is used, for example.

In FIG. 17, FIG. 18, and FIG. 19, regions where reference numerals and hatching patterns are not given show regions formed of an insulator. As an insulator of the semiconductor, an insulator containing one or more of aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, tantalum oxide, and the like can be used. Alternatively, in these regions, an organic resin such as a polyimide resin, a polyamide resin, an acrylic resin, a siloxane resin, an epoxy resin, or a phenol resin can be used. Note that in this specification, an oxynitride refers to a substance that contains more oxygen than nitrogen, and a nitride oxide refers to a substance that contains more nitrogen than oxygen.

At least one of insulating layers 351 to 354 is preferably a layer which is formed using an insulator having a blocking effect against hydrogen, water, and the like. Since hydrogen, water, and the like cause generation of carriers in an oxide semiconductor, providing the blocking layer against hydrogen, water, and the like can improve the reliability of the OS transistors formed in the element layers 301 and 302. Examples of the insulator having a blocking effect against hydrogen, water, and the like include aluminum oxide, aluminum oxynitride, gallium oxide, gallium oxynitride, yttrium oxide, yttrium oxynitride, hafnium oxide, hafnium oxynitride, and yttria-stabilized zirconia (YSZ).

The insulators, the conductors, and the semiconductors included in the semiconductor device can be formed by a sputtering method, a chemical vapor deposition (CVD) method, a molecular beam epitaxy (MBE) method, an atomic layer deposition (ALD) method, a pulsed laser deposition (PLD) method, or the like. A CVD method includes a thermal CVD method, a metal organic CVD (MOCVD) method, and a plasma enhanced CVD (PECVD) method. For example, it is preferable that an insulating film be formed by a CVD method, further preferably a PECVD method because coverage can be improved. In the case where an insulating film is formed by a CVD method, it is preferable to use a thermal CVD method, an MOCVD method, or an ALD method in order to reduce plasma damage.

Fine processing technique such as nanoimprint lithography (including hot embossing) and injection molding may be used to form the MEMS device (the element layer 304).

### <<Electronic Component>>

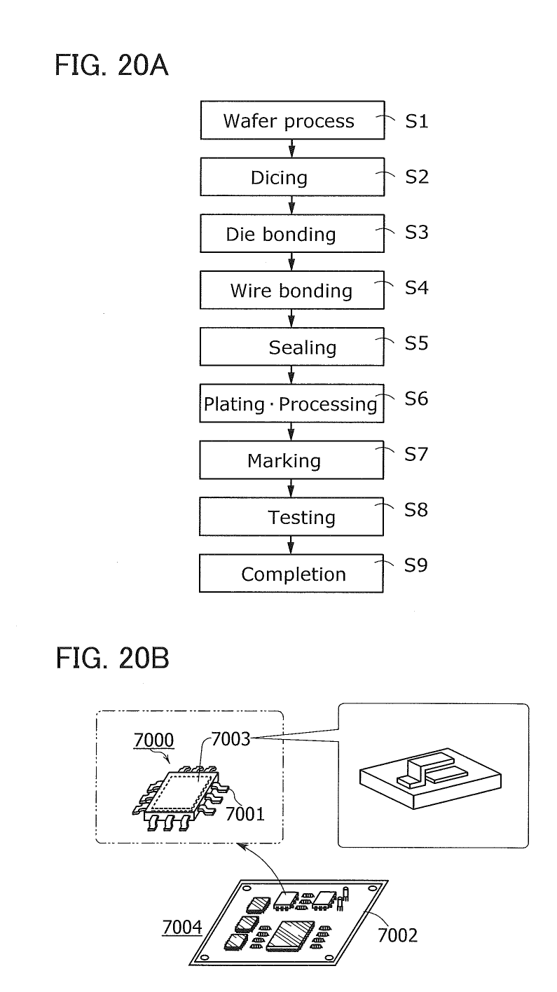

The semiconductor devices illustrated in FIG. 17, FIG. 18, and FIG. 19 are processed into packaged electronic components. FIG. 20A is a flow chart showing an example of a method for manufacturing an electronic component. The electronic component is also referred to as a semiconductor package or an IC package. The packaged semiconductor device has a plurality of standards and names in accordance with a terminal extraction direction and a terminal shape. Here, an example thereof is described.

In a wafer process, semiconductor devices are manufactured over a semiconductor wafer (Step S1). A process from Steps S2 to S8 is called an assembly and testing process. To separate the semiconductor devices into individual chips, a dicing step is performed (Step S2). To protect the MEMS devices, a sealing substrate (e.g., a glass substrate or a semiconductor wafer) is bonded to the semiconductor wafer. To thin the semiconductor wafer, the rear surface of the semiconductor wafer is ground. After that, the semiconductor wafer is cut so that the semiconductor devices are separated into individual chips.

A die bonding step in which the chips are individually picked up to be mounted and bonded on the lead frame is performed (Step S3). A bonding method suitable for the product may be selected; for example, the chips and the lead frame may be bonded with a resin or tape. Note that in the die bonding step, a chip may be mounted on and bonded to an interposer. In a wire bonding step, a lead of the lead frame and an electrode on the chip are electrically connected to each other with a metal wire (Step S4). As the metal wire, a silver wire or a gold wire can be used. The wire bonding may be performed by either of ball bonding or wedge bonding.

A wire-bonded chip is subjected to a molding step of sealing the chip with an epoxy resin or the like (Step S5). The lead of the lead frame is plated. Then, the lead is cut and processed into a predetermined shape (Step S6). With the plating process, corrosion of the lead can be prevented, and soldering for mounting the chip on a printed wiring board in a later step can be performed with higher reliability. A marking step for printing the product name, the lot number, and the like on the package is performed (Step S7). After a testing step (Step S8), the electronic component is completed (Step S9).

In the semiconductor devices illustrated in FIG. 17, FIG. 18, and FIG. 19, the MEMS device (the element layer 304) and a circuit portion that includes the OS transistors and is configured to control the MEMS device may be formed over different semiconductor wafers. In this case, a chip where the MEMS device is formed and a chip where the circuit portion is faulted are electrically connected to each other to be incorporated in one package.

FIG. 20B is a perspective schematic view of a completed electronic component. FIG. 20B shows a perspective schematic view of a quad flat package (QFP) as an example of the electronic component. As illustrated in FIG. 20B, an electronic component 7000 includes a lead 7001 and a circuit portion 7003. In the circuit portion 7003, for example, any of the semiconductor devices in FIG. 17, FIG. 18, and FIG. 19 is formed. The electronic component 7000 is mounted on a printed board 7002, for example. Plural kinds of electronic components 7000 are combined to be electrically connected to each other over the printed board 7002, whereby a circuit board 7004 can be formed. The completed circuit board 7004 is mounted on any of the various electronic devices mentioned in Embodiment 1.

### Embodiment 3

A structure of an oxide semiconductor and the like are described in this embodiment.

### <<Structure of Oxide Semiconductor>>

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a microcrystalline oxide semiconductor, and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and a microcrystalline oxide semiconductor.

### <CAAC-OS>

A CAAC-OS is one of oxide semiconductors having a plurality of c-axis-aligned crystal parts (also referred to as pellets). Note that a CAAC-OS can be referred to as an oxide semiconductor including c-axis aligned nanocrystals (CANC).

### (TEM)

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

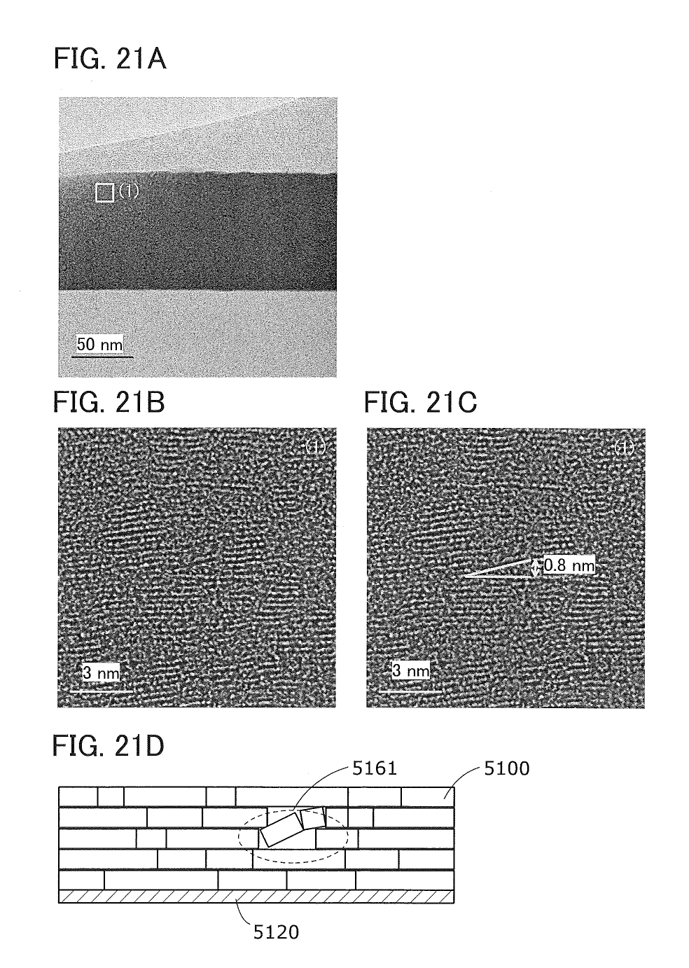

FIG. 21A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 21B is an enlarged Cs-corrected high-resolution TEM image of a region (1) in FIG. 21A. FIG. 21B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 21B, the CAAC-OS has a characteristic atomic arrangement. The characteristic atomic arrangement is denoted by an auxiliary line in FIG. 21C. FIGS. 21B and 21C prove that the size of a pellet is approximately 1 nm to 3 nm, and the size of a space caused by tilt of the pellets is approximately 0.8 nm. Therefore, the pellet can also be referred to as a nanocrystal (nc).

Here, according to the Cs-corrected high-resolution TEM images, the schematic arrangement of pellets 5100 of a CAAC-OS over a substrate 5120 is illustrated by such a structure in which bricks or blocks are stacked (see FIG. 21D). The part in which the pellets are tilted as observed in FIG. 21C corresponds to a region 5161 shown in FIG. 21D.

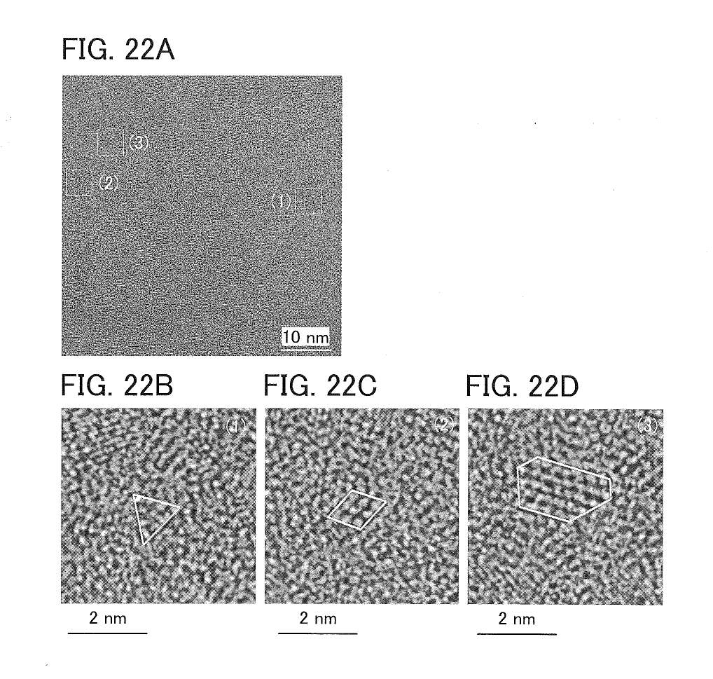

FIG. 22A shows a Cs-corrected high-resolution TEM image of a plane of the CAAC-OS observed from a direction substantially perpendicular to the sample surface. FIGS. 22B, 22C, and 22D are enlarged Cs-corrected high-resolution TEM images of regions (1), (2), and (3) in FIG. 22A, respectively. FIGS. 22B, 22C, and 22D indicate that metal atoms are arranged in a triangular, quadrangular, or hexagonal configuration in a pellet. However, there is no regularity of arrangement of metal atoms between different pellets.

### (XRD)

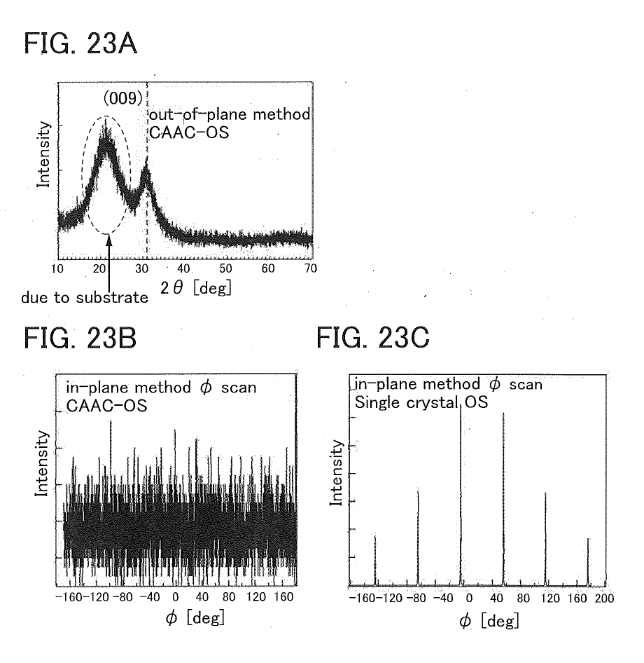

Next, the CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 23A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

In structural analysis of the CAAC-OS by an in-plane method in which an X-ray is incident on a sample in a direction substantially perpendicular to the c-axis, a peak appears when 2θ is around 56°. This peak is derived from the (110) plane of the InGaZnO₄ crystal. In the case of the CAAC-OS, when analysis (φ scan) is performed with 2θ fixed at around 56° and with the sample rotated about a normal vector of the sample surface as an axis (φ axis), as shown in FIG. 23B, a peak is not clearly observed. In contrast, in the case of a single crystal oxide semiconductor of InGaZnO₄, when 0 scan is performed with 2θ fixed at around 56°, six peaks which are derived from crystal planes equivalent to the (110) plane are observed, as shown in FIG. 23C. Accordingly, the structural analysis using XRD shows that the directions of a-axes and b-axes are irregularly oriented in the CAAC-OS.

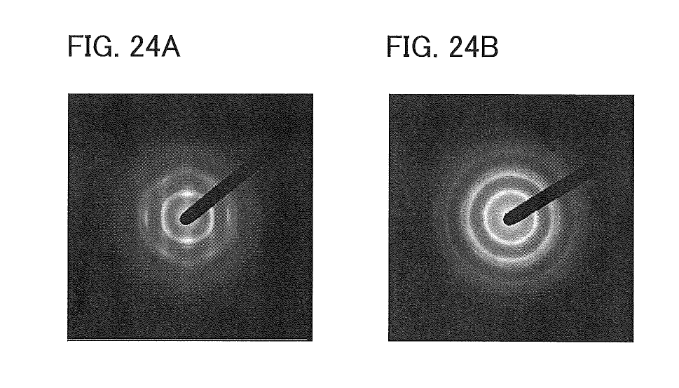

Next, a CAAC-OS layer analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 24A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, a ring-like diffraction pattern as shown in FIG. 24B is observed when an electron beam with a probe diameter of 300 nm is incident on the same sample in a direction perpendicular to the sample surface. Thus, the electron diffraction also indicates that the a-axes and b-axes of the pellets included in the CAAC-OS do not have regular alignment. The first ring in FIG. 24B is considered to be derived from the (010) plane, the (100) plane, and the like of the InGaZnO₄ crystal. The second ring in FIG. 24B is considered to be derived from the (110) plane and the like.

Thus, the CAAC-OS is an oxide semiconductor having a low density of defect states. Defects in the oxide semiconductor are, for example, a defect due to impurity and oxygen vacancies. Therefore, the CAAC-OS can be regarded as an oxide semiconductor with a low impurity concentration, or an oxide semiconductor having a small number of oxygen vacancies.

The impurity contained in the oxide semiconductor might serve as a carrier trap or serve as a carrier generation source. Furthermore, oxygen vacancies in the oxide semiconductor serve as carrier traps or serve as carrier generation sources when hydrogen is captured therein.

The impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

An oxide semiconductor having low density of defect states (a small number of oxygen vacancies) can have low carrier density. Such an oxide semiconductor is referred to as a highly purified intrinsic or substantially highly purified intrinsic oxide semiconductor. A CAAC-OS has a low impurity concentration and a low density of defect states. That is, a CAAC-OS is likely to be highly purified intrinsic or substantially highly purified intrinsic oxide semiconductors. Thus, a transistor including a CAAC-OS rarely has negative threshold voltage (is rarely normally on). Therefore, a transistor including a CAAC-OS or an nc-OS has small variation in electrical characteristics and high reliability. An electric charge trapped by the carrier traps in the oxide semiconductor takes a long time to be released. The trapped electric charge may behave like a fixed electric charge. Thus, the transistor which includes the oxide semiconductor having a high impurity concentration and a high density of defect states might have unstable electrical characteristics. However, a transistor including a CAAC-OS has small variation in electrical characteristics and high reliability.

Since the CAAC-OS has a low density of defect states, the number of carriers trapped in defect states by light irradiation is small. Therefore, in a transistor using the CAAC-OS, change in electrical characteristics due to irradiation with visible light or ultraviolet light is small.

### <Microcrystalline Oxide Semiconductor>

A microcrystalline oxide semiconductor has a region in which a crystal part is observed and a region in which a crystal part is not observed clearly in a high-resolution TEM image. In most cases, the size of a crystal part included in the microcrystalline oxide semiconductor is greater than or equal to 1 nm and less than or equal to 100 nm, or greater than or equal to 1 nm and less than or equal to 10 nm. An oxide semiconductor including a nanocrystal that is a microcrystal with a size greater than or equal to 1 nm and less than or equal to 10 nm, or a size greater than or equal to 1 nm and less than or equal to 3 nm is specifically referred to as a nanocrystalline oxide semiconductor (nc-OS). In a high-resolution TEM image of the nc-OS film, for example, a grain boundary is not always found clearly. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, in some cases, the nc-OS cannot be distinguished from an amorphous oxide semiconductor, depending on an analysis method. For example, when the nc-OS is subjected to structural analysis by an out-of-plane method with an XRD apparatus using an X-ray having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet (the electron diffraction is also referred to as selected-area electron diffraction). Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS layer, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an amorphous oxide semiconductor. Note that there is no regularity of crystal orientation between different pellets in the nc-OS. Therefore, the nc-OS has a higher density of defect states than the CAAC-OS.

### <Amorphous Oxide Semiconductor>

The amorphous oxide semiconductor is such an oxide semiconductor having disordered atomic arrangement and no crystal part. For example, the amorphous oxide semiconductor does not have a specific state as in quartz.

In a high-resolution TEM image of the amorphous oxide semiconductor, crystal parts cannot be found.

When the amorphous oxide semiconductor is subjected to structural analysis by an out-of-plane method with an XRD apparatus, a peak which shows a crystal plane does not appear. A halo pattern is observed when the amorphous oxide semiconductor is subjected to electron diffraction. Furthermore, a spot is not observed and only a halo pattern appears when the amorphous oxide semiconductor is subjected to nanobeam electron diffraction.

There are various understandings of an amorphous structure. For example, a structure whose atomic arrangement does not have ordering at all is called a completely amorphous structure. Meanwhile, a structure which has ordering until the nearest neighbor atomic distance or the second-nearest neighbor atomic distance but does not have long-range ordering is also called an amorphous structure. Therefore, the strictest definition does not permit an oxide semiconductor to be called an amorphous oxide semiconductor as long as even a negligible degree of ordering is present in an atomic arrangement. At least an oxide semiconductor having long-term ordering cannot be called an amorphous oxide semiconductor. Accordingly, because of the presence of a crystal part, for example, a CAAC-OS and an nc-OS cannot be called an amorphous oxide semiconductor or a completely amorphous oxide semiconductor.

### <Amorphous-Like Oxide Semiconductor>

Note that an oxide semiconductor may have a structure intermediate between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be observed. Furthermore, in the high-resolution TEM image, there are a region where a crystal part is clearly observed and a region where a crystal part is not observed.

The a-like OS has an unstable structure because it includes a void. To verify that an a-like OS has an unstable structure as compared with a CAAC-OS and an nc-OS, a change in structure caused by electron irradiation is described below.

An a-like OS (Sample A), an nc-OS (Sample B), and a CAAC-OS (Sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts. Note that which part is regarded as a crystal part is determined as follows.

It is known that a unit cell of the InGaZnO₄ crystal has a structure in which nine layers including three In—O layers and six Ga—Zn—O layers are stacked in the c-axis direction. The spacing between these adjacent layers is equivalent to the lattice spacing on the (009) plane (also referred to as d value). The value is calculated to 0.29 nm from crystal structure analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

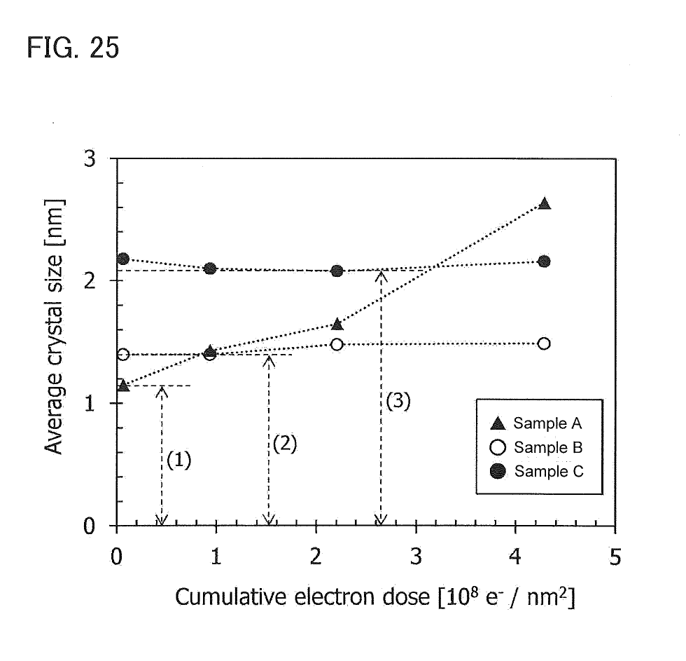

FIG. 25 shows change in the average size of crystal parts (at 22 points to 45 points) in each sample. Note that the crystal part size corresponds to the length of a lattice fringe. FIG. 25 indicates that the crystal part size in the a-like OS increases with an increase in the cumulative electron dose. Specifically, as shown by (1) in FIG. 25, a crystal part of approximately 1.2 nm at the start of TEM observation (the crystal part is also referred to as an initial nucleus) grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 25, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it includes a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor layer having a density of lower than 78% of the density of the single crystal oxide semiconductor layer.

For example, in the case of an oxide semiconductor having an atomic ratio of In:Ga:′ Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. It is preferable to use as few kinds of single crystal oxide semiconductors as possible to calculate the density.

As described above, oxide semiconductors have various structures and various properties. Note that an oxide semiconductor may be a stacked film including two or more films of an amorphous oxide semiconductor, an a-like OS, a microcrystalline oxide semiconductor, and a CAAC-OS, for example.

### <Deposition Model>

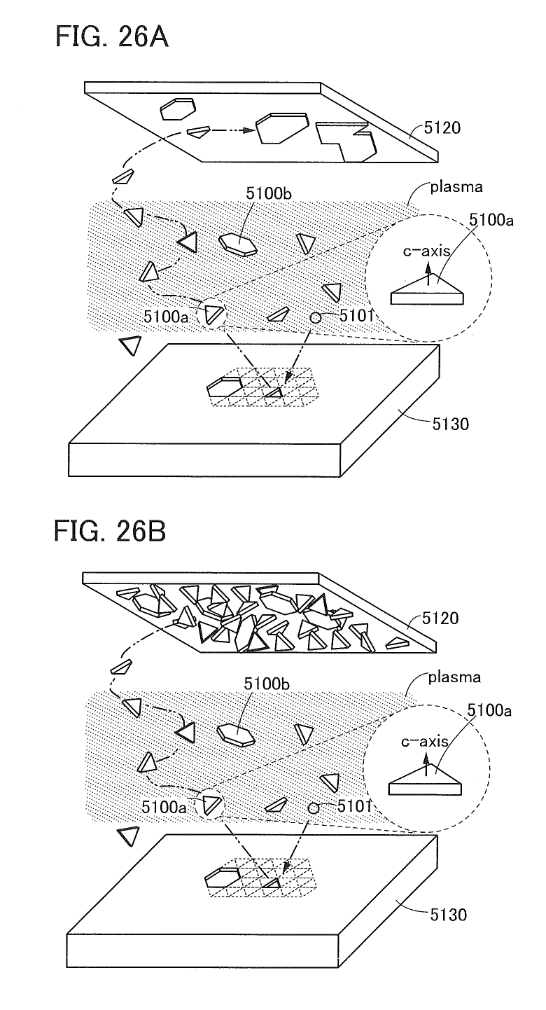

Examples of deposition models of a CAAC-OS and an nc-OS are described below. FIG. 26A is a schematic view of the inside of a deposition chamber where a CAAC-OS layer is deposited by a sputtering method.

A target 5130 is attached to a backing plate. A plurality of magnets are provided to face the target 5130 with the backing plate positioned therebetween. The plurality of magnets generate a magnetic field. A sputtering method in which the disposition speed is increased by utilizing a magnetic field of magnets is referred to as a magnetron sputtering method.

A substrate 5120 is placed to face the target 5130, and the distance d (also referred to as a target-substrate distance (T-S distance)) is greater than or equal to 0.01 m and less than or equal to 1 m, preferably greater than or equal to 0.02 in and less than or equal to 0.5 in. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a constant value or higher to the target 5130, and plasma is observed. The magnetic field forms a high-density plasma region in the vicinity of the target 5130. In the high-density plasma region, the deposition gas is ionized, so that an ion 5101 is generated. Examples of the ion 5101 include an oxygen cation (O⁺) and an argon cation (Ar⁺).

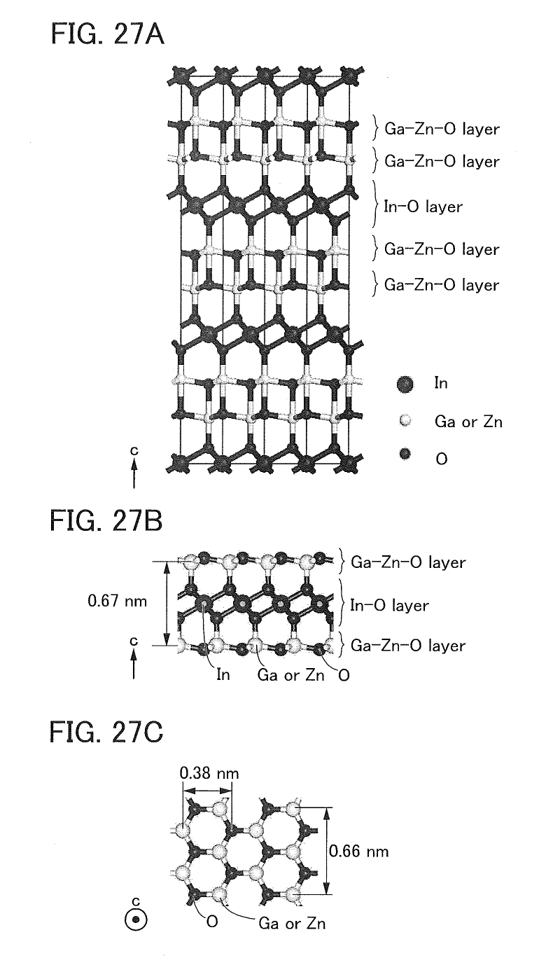

Here, the target 5130 has a polycrystalline structure which includes a plurality of crystal grains and in which a cleavage plane exists in at least one crystal grain. FIG. 27A shows a structure of an InGaZnO₄ crystal included in the target 5130 as an example. Note that FIG. 27A shows a structure of the case where the InGaZnO₄ crystal is observed from a direction parallel to the b-axis when the c-axis is in an upward direction. FIG. 27A indicates that oxygen atoms in a Ga—Zn—O layer are positioned close to those in an adjacent Ga—Zn—O layer. The oxygen atoms have negative charge, whereby repulsive force is generated between the two Ga—Zn—O layers. As a result, the InGaZnO₄ crystal has a cleavage plane between the two adjacent Ga—Zn—O layers.

The ion 5101 generated in the high-density plasma region is accelerated toward the target 5130 side by an electric field, and then collides with the target 5130. At this time, a pellet 5100a and a pellet 5100b which are flat-plate-like (pellet-like) sputtered particles are separated and sputtered from the cleavage plane. Note that structures of the pellet 5100a and the pellet 5100b may be distorted by an impact of collision of the ion 5101.

The pellet 5100a is a flat-plate-like (pellet-like) sputtered particle having a triangle plane, e.g., regular triangle plane. The pellet 5100b is a flat-plate-like (pellet-like) sputtered particle having a hexagon plane, e.g., regular hexagon plane. Note that flat-plate-like (pellet-like) sputtered particles such as the pellet 5100a and the pellet 5100b are collectively called pellets 5100. The shape of a flat plane of the pellet 5100 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5100 is determined depending on the kind of deposition gas and the like. The thicknesses of the pellets 5100 are preferably uniform; the reasons thereof are described later. In addition, the sputtered particle preferably has a pellet shape with a small thickness as compared to a dice shape with a large thickness. For example, the thickness of the pellet 5100 is greater than or equal to 0.4 nm and less than or equal to 1 nm, preferably greater than or equal to 0.6 nm and less than or equal to 0.8 nm. In addition, for example, the width of the pellet 5100 is greater than or equal to 1 nm and less than or equal to 3 nm, preferably greater than or equal to 1.2 nm and less than or equal to 2.5 nm. The pellet 5100 corresponds to the initial nucleus in the description of (1) in FIG. 25. For example, when the ion 5101 collides with the target 5130 including an In—Ga—Zn oxide, the pellet 5100 that includes three layers of a Ga—Zn—O layer, an In—O layer, and a Ga—Zn—O layer as shown in FIG. 27B is separated. Note that FIG. 27C shows the structure of the separated pellet 5100 which is observed from a direction parallel to the c-axis. The pellet 5100 has a nanometer-sized sandwich structure including two Ga—Zn—O layers (pieces of bread) and an In—O layer (filling).

The pellet 5100 may receive a charge when passing through the plasma, so that side surfaces thereof are negatively or positively charged. In the pellet 5100, an oxygen atom positioned on its side surface may be negatively charged. In this manner, when the side surfaces are charged with the same polarity, charges repel each other, and accordingly, the pellet 5100 can maintain a flat-plate shape. In the case where a CAAC-OS is an In—Ga—Zn oxide, there is a possibility that an oxygen atom bonded to an indium atom is negatively charged. There is another possibility that an oxygen atom bonded to an indium atom, a gallium atom, or a zinc atom is negatively charged. In addition, the pellet 5100 may grow by being bonded with an indium atom, a gallium atom, a zinc atom, an oxygen atom, or the like when passing through plasma. A difference in size between (2) and (1) in FIG. 25 corresponds to the amount of growth in plasma. Here, in the case where the temperature of the substrate 5120 is at around room temperature, the pellet 5100 on the substrate 5120 hardly grows; thus, an nc-OS is formed (see FIG. 26B). An nc-OS can be deposited when the substrate 5120 has a large size because the deposition of an nc-OS can be carried out at room temperature. Note that in order that the pellet 5100 grows in plasma, it is effective to increase deposition power in sputtering. High deposition power can stabilize the structure of the pellet 5100.

As shown in FIGS. 26A and 26B, the pellet 5100 flies like a kite in plasma and flutters up to the substrate 5120. Since the pellets 5100 are charged, when the pellet 5100 gets close to a region where another pellet 5100 has already been deposited, repulsion is generated. Here, above the substrate 5120, a magnetic field in a direction parallel to the top surface of the substrate 5120 (also referred to as a horizontal magnetic field) is generated. A potential difference is given between the substrate 5120 and the target 5130, and accordingly, current flows from the substrate 5120 toward the target 5130. Thus, the pellet 5100 is given a force (Lorentz force) on the top surface of the substrate 5120 by an effect of the magnetic field and the current. This is explainable with Fleming's left-hand rule.

The mass of the pellet 5100 is larger than that of an atom. Therefore, to move the pellet 5100 over the top surface of the substrate 5120, it is important to apply some force to the pellet 5100 from the outside. One kind of the force may be force which is generated by the action of a magnetic field and current. In order to apply a sufficient force to the pellet 5100 so that the pellet 5100 moves over a top surface of the substrate 5120, it is preferable to provide, on the top surface, a region where the magnetic field in a direction parallel to the top surface of the substrate 5120 is 10 G or higher, preferably 2θ G or higher, further preferably 30 G or higher, still further preferably 50 G or higher. Alternatively, it is preferable to provide, on the top surface, a region where the magnetic field in a direction parallel to the top surface of the substrate 5120 is 1.5 times or higher, preferably twice or higher, further preferably 3 times or higher, still further preferably 5 times or higher as high as the magnetic field in a direction perpendicular to the top surface of the substrate 5120.

At this time, the magnets and the substrate 5120 are moved or rotated relatively, whereby the direction of the horizontal magnetic field on the top surface of the substrate 5120 continues to change. Therefore, the pellet 5100 can be moved in various directions on the top surface of the substrate 5120 by receiving forces in various directions.

Furthermore, as shown in FIG. 26A, when the substrate 5120 is heated, resistance between the pellet 5100 and the substrate 5120 due to friction or the like is low. As a result, the pellet 5100 glides above the top surface of the substrate 5120. The glide of the pellet 5100 is caused in a state where the flat plane faces the substrate 5120. Then, when the pellet 5100 reaches the side surface of another pellet 5100 that has been already deposited, the side surfaces of the pellets 5100 are bonded. At this time, the oxygen atom on the side surface of the pellet 5100 is released. With the released oxygen atom, oxygen vacancies in a CAAC-OS is filled in some cases; thus, the CAAC-OS has a low density of defect states. Note that the temperature of the top surface of the substrate 5120 is, for example, higher than or equal to 100° C. and lower than 500° C., higher than or equal to 150° C. and lower than 450° C., or higher than or equal to 170° C. and lower than 400° C. Hence, even when the substrate 5120 has a large size, it is possible to deposit a CAAC-OS.

Furthermore, the pellet 5100 is heated on the substrate 5120, whereby atoms are rearranged, and the structure distortion caused by the collision of the ion 5101 can be reduced. The pellet 5100 whose structure distortion is reduced is substantially single crystal. Even when the pellets 5100 are heated after being bonded, expansion and contraction of the pellet 5100 itself hardly occur, which is caused by turning the pellet 5100 into substantially single crystal. Thus, formation of defects such as a grain boundary due to expansion of a space between the pellets 5100 can be prevented, and accordingly, generation of crevasses can be prevented.

The CAAC-OS does not have a structure like a board of a single crystal oxide semiconductor but has arrangement with a group of pellets 5100 (nanocrystals) like stacked bricks or blocks. Furthermore, a grain boundary does not exist between the pellets 5100. Therefore, even when deformation such as shrink occurs in the CAAC-OS owing to heating during deposition, heating or bending after deposition, it is possible to relieve local stress or release distortion. Therefore, this structure is suitable for a flexible semiconductor device. Note that the nc-OS has arrangement in which pellets 5100 (nanocrystals) are randomly stacked.

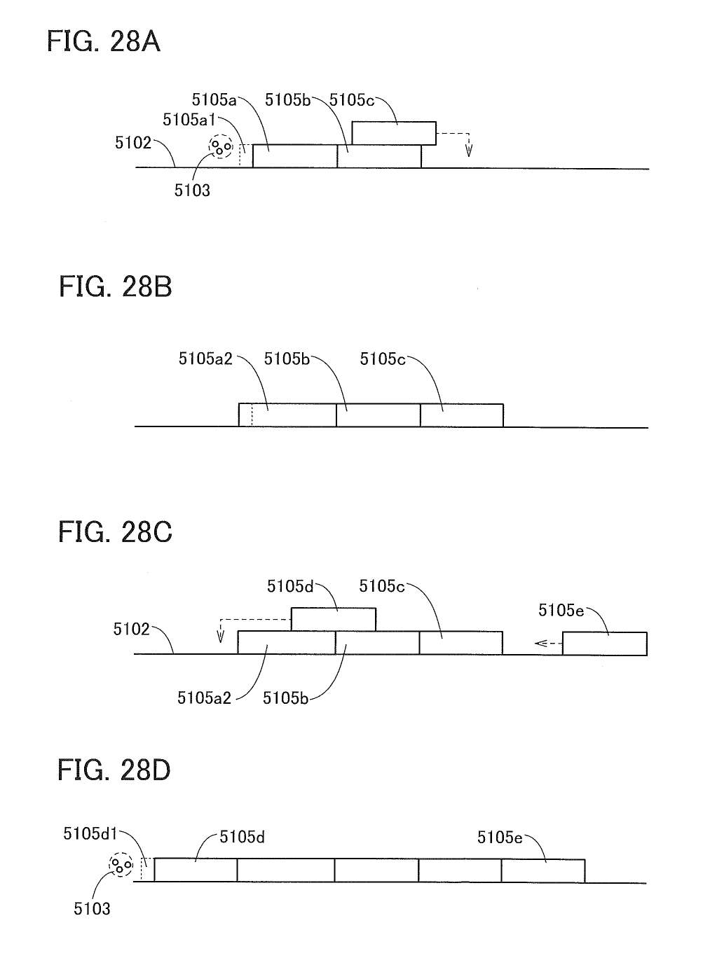

When the target 5130 is sputtered with the ion 5101, in addition to the pellets 5100, zinc oxide or the like may be separated. The zinc oxide is lighter than the pellet and thus reaches the top surface of the substrate 5120 before the pellet. As a result, the zinc oxide forms a zinc oxide layer 5102 with a thickness greater than or equal to 0.1 nm and less than or equal to 10 nm, greater than or equal to 0.2 nm and less than or equal to 5 nm, or greater than or equal to 0.5 nm and less than or equal to 2 nm. FIGS. 28A to 28D are cross-sectional schematic views.

As illustrated in FIG. 28A, a pellet 5105a and a pellet 5105b are deposited over the zinc oxide layer 5102. Here, side surfaces of the pellet 5105a and the pellet 5105b are in contact with each other. In addition, a pellet 5105c is deposited over the pellet 5105b, and then glides over the pellet 5105b. Furthermore, a plurality of particles 5103 separated from the target together with the zinc oxide is crystallized by heating of the substrate 5120 to form a region 5105a1 on another side surface of the pellet 5105a. Note that the plurality of particles 5103 may contain oxygen, zinc, indium, gallium, or the like.

Then, as illustrated in FIG. 28B, the region 5105a1 grows to part of the pellet 5105a to form a pellet 5105a2. In addition, a side surface of the pellet 5105c is in contact with another side surface of the pellet 5105b.

Next, as illustrated in FIG. 28C, a pellet 5105d is deposited over the pellet 5105a2 and the pellet 5105b, and then glides over the pellet 5105a2 and the pellet 5105b. Furthermore, a pellet 5105e glides toward another side surface of the pellet 5105c over the zinc oxide layer 5102.

Then, as illustrated in FIG. 28D, the pellet 5105d is placed so that a side surface of the pellet 5105d is in contact with a side surface of the pellet 5105a2.

Furthermore, a side surface of the pellet 5105e is in contact with another side surface of the pellet 5105c. A plurality of particles 5103 separated from the target 5130 together with the zinc oxide is crystallized by heating of the substrate 5120 to form a region 5105d1 on another side surface of the pellet 5105d.

As described above, deposited pellets are placed to be in contact with each other and then growth is caused at side surfaces of the pellets, whereby a CAAC-OS is formed over the substrate 5120. Therefore, each pellet of the CAAC-OS is larger than that of the nc-OS. A difference in size between (3) and (2) in FIG. 25 corresponds to the amount of growth after deposition.

When spaces between pellets are extremely small, the pellets may form a large pellet. The large pellet has a single crystal structure. For example, the size of the pellet may be greater than or equal to 10 nm and less than or equal to 200 nm, greater than or equal to 15 nm and less than or equal to 100 nm, or greater than or equal to 2θ nm and less than or equal to 50 nm, when seen from the above. In this case, in an oxide semiconductor used for a minute transistor, a channel region might be fit inside the large pellet. That is, the region having a single crystal structure can be used as the channel region. Furthermore, when the size of the pellet is increased, the region having a single crystal structure can be used as the channel region, the source region, and the drain region of the transistor.

In this manner, when the channel region or the like of the transistor is formed in a region having a single crystal structure, the frequency characteristics of the transistor can be increased in some cases.

It is considered that as shown in such a model, the pellets 5100 are deposited on the substrate 5120. Thus, a CAAC-OS can be deposited even when a formation surface does not have a crystal structure; therefore, a growth mechanism in this case is different from epitaxial growth. In addition, laser crystallization is not needed for formation of a CAAC-OS, and a uniform film can be formed even over a large-sized glass substrate or the like. For example, even when the top surface (formation surface) of the substrate 5120 has an amorphous structure (e.g., the top surface is formed of amorphous silicon oxide), a CAAC-OS can be formed.

In addition, it is found that in formation of the CAAC-OS, the pellets 5100 are arranged in accordance with the top surface shape of the substrate 5120 that is the formation surface even when the formation surface has unevenness. For example, in the case where the top surface of the substrate 5120 is flat at the atomic level, the pellets 5100 are arranged so that flat planes parallel to the a-b plane face downwards. In the case where the thicknesses of the pellets 5100 are uniform, a layer with a uniform thickness, flatness, and high crystallinity is formed. By stacking n layers (n is a natural number), the CAAC-OS can be obtained.

In the case where the top surface of the substrate 5120 has unevenness, a CAAC-OS in which n layers (n is a natural number) in each of which the pellets 5100 are arranged along the unevenness are stacked is formed. Since the substrate 5120 has unevenness, a gap is easily generated between the pellets 5100 in the CAAC-OS in some cases. Note that owing to intermolecular force, the pellets 5100 are arranged so that a gap between the pellets 5100 is as small as possible even on the unevenness surface. Therefore, even when the formation surface has unevenness, a CAAC-OS with high crystallinity can be formed.

Since the CAAC-OS film is deposited in accordance with such a model, the sputtered particle preferably has a pellet shape with a small thickness. Note that when the sputtered particles has a dice shape with a large thickness, planes facing the substrate 5120 vary, which may lead to formation of a film whose thickness or crystal alignment is not uniformed. According to the deposition model described above, a CAAC-OS with high crystallinity can be formed even on a film formation surface with an amorphous structure.

In this specification, the term “parallel” indicates that the angle formed between two straight lines is greater than or equal to −10° and less than or equal to 10°, and accordingly also includes the case where the angle is greater than or equal to −5° and less than or equal to 5°. A term “substantially parallel” indicates that the angle formed between two straight lines is greater than or equal to −30° and less than or equal to 30°. In addition, the term “perpendicular” indicates that the angle formed between two straight lines is greater than or equal to 80° and less than or equal to 100°, and accordingly also includes the case where the angle is greater than or equal to 85° and less than or equal to 95°. A term “substantially perpendicular” indicates that the angle formed between two straight lines is greater than or equal to 60° and less than or equal to 120°. In this specification, trigonal and rhombohedral crystal systems are included in a hexagonal crystal system.

This application is based on Japanese Patent Application serial no. 2014-218013 filed with Japan Patent Office on Oct. 27, 2014, the entire contents of which are hereby incorporated by reference.

What is claimed is:

1. An oscillator circuit comprising:
a MEMS switch;
a capacitor;
a buffer circuit;
a first transistor;
a second transistor;
a first node; and
a second node,
wherein the MEMS switch comprises a movable electrode and a fixed electrode,
wherein the fixed electrode is electrically connected to the first node,
wherein a first terminal of the capacitor is electrically connected to the first node,
wherein an input terminal of the buffer circuit is electrically connected to the first node,
wherein a first terminal of the first transistor is electrically connected to the second node,
wherein the first transistor comprises a channel formation region comprising an oxide semiconductor,
wherein a gate of the second transistor is electrically connected to the second node, and
wherein a first terminal of the second transistor is electrically connected to the first node.

2. The oscillator circuit according to claim 1, wherein the second transistor comprises a channel formation region comprising an oxide semiconductor.

3. A phase locked loop comprising the oscillator circuit according to claim 1.

4. An electronic component comprising:
a chip; and
a lead,
wherein the chip includes the oscillator circuit according to claim 1, and
wherein the lead is electrically connected to the chip.

5. An electronic device comprising:
the oscillator circuit according to claim 1; and
at least one of a display device, a touch panel, a microphone, a speaker, an operation key, and a housing.

6. An oscillator circuit comprising:
a MEMS switch;
a capacitor;
a buffer circuit;
n circuits;
a multiplexer;
a first node;
n first wirings; and
a second wiring,
wherein the MEMS switch comprises a movable electrode and a fixed electrode,
wherein the fixed electrode is electrically connected to the first node,
wherein a first terminal of the capacitor is electrically connected to the first node,
wherein an input terminal of the buffer circuit is electrically connected to the first node,
wherein the n circuits are electrically connected to the respective first wirings,
wherein the n circuits are electrically connected to the second wiring,
wherein the n circuits each comprise a first transistor, a second transistor, and a second node,
wherein a first terminal of the first transistor is electrically connected to the second node,
wherein a second terminal of the first transistor is electrically connected to the second wiring,
wherein the first transistor comprises a channel formation region comprising an oxide semiconductor,
wherein a gate of the second transistor is electrically connected to the second node,
wherein a first terminal of the second transistor is electrically connected to the multiplexer, and
wherein the multiplexer is configured to select one of the n circuits and establish electrical continuity between the first node and the first terminal of the second transistor of the selected circuit.

7. The oscillator circuit according to claim 6, wherein the second transistor comprises a channel formation region comprising an oxide semiconductor.

8. The oscillator circuit according to claim 6,
wherein the multiplexer comprises n third transistors, and
wherein the n third transistors are each configured to control a conduction state between the first node and the first terminal of the corresponding second transistor.

9. The oscillator circuit according to claim 8, wherein each of the n third transistors comprises a channel formation region comprising an oxide semiconductor.

10. A phase locked loop comprising the oscillator circuit according to claim 6.

11. An electronic component comprising:
a chip; and
a lead,
wherein the chip includes the oscillator circuit according to claim 6, and
wherein the lead is electrically connected to the chip.

12. An electronic device comprising:
the oscillator circuit according to claim 6; and
at least one of a display device, a touch panel, a microphone, a speaker, an operation key, and a housing.
